(19) United States
(12) Patent Application Publication
(10) Pub. No.: US 2025/0151382 A1
(43) Pub. Date: May 8, 2025

(54) SEMICONDUCTOR DEVICE

(71) Applicant: SAMSUNG ELECTRONICS CO., LTD., SUWON-SI (KR)

(72) Inventors: Hye In CHUNG, Suwon-si (KR); Dong-Gwan SHIN, Suwon-si (KR); Yeon Ho PARK, Suwon-si (KR); Yong Hee PARK, Suwon-si (KR); Hong Seon YANG, Suwon-si (KR)

(21) Appl. No.: 18/663,258

(22) Filed: May 14, 2024

(30) Foreign Application Priority Data
Nov. 7, 2023 (KR) 10-2023-0152329

(51) Int. Cl. H01L 27/088; H01L 21/8234; H01L 29/06; H01L 29/417; H01L 29/78

(52) U.S. Cl. CPC H10D 84/834; H10D 30/6215; H10D 30/6219; H10D 62/121; H10D 84/0151; H10D 84/038

(57) ABSTRACT

A semiconductor device includes a first gate isolation structure. A second gate isolation structure is spaced apart from the first gate isolation structure in a first direction. A first active pattern is disposed between the first and second gate isolation structures. The first active pattern extends longitudinally in a second direction crossing the first direction. A second active pattern is disposed between the first and second gate isolation structures. The second active pattern extends longitudinally in the second direction and is spaced apart from the first active pattern in the first direction. Gate structures are disposed between the first and second gate isolation structures. The gate structures directly contact the first and second gate isolation structures. A length of the first gate isolation structure in the second direction is greater than a length of the second gate isolation structure in the second direction.

### CROSS-REFERENCE TO RELATED APPLICATION

This application claims priority under 35 U.S.C. § 119 to Korean Patent Application No. 10-2023-0152329, filed on Nov. 7, 2023 in the Korean Intellectual Property Office, the disclosure of which is incorporated by reference in its entirety herein.

### 1. TECHNICAL FIELD

The present disclosure relates to a semiconductor device.

### 2. DISCUSSION OF RELATED ART

Multi-gate transistors are being developed as one of the scaling technologies to increase the density of semiconductor devices. The multi-gate transistors are obtained by forming multi-channel active patterns (e.g., silicon bodies) in the shape of fins or nanowires on a substrate and then forming gates on the surfaces of the multi-channel active patterns.

The multi-gate transistors are easier to scale due to the utilization of three-dimensional (3D) channels. The multi-gate transistors can also increase current control capabilities without increasing the gate length of the transistor. Additionally, the multi-gate transistors can effectively suppress the short channel effect (SCE) in which the potential in a channel area is affected by the drain voltage.

However, as the pitch size of semiconductor devices decreases, research is needed to reduce parasitic capacitance and to ensure electrical stability between contacts within a semiconductor device.

### SUMMARY

Aspects of embodiments of the present disclosure provide a semiconductor device that can increase device performance and reliability.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of embodiments of the present disclosure given below.

According to an embodiment of the present disclosure, a semiconductor device includes a first gate isolation structure. A second gate isolation structure is spaced apart from the first gate isolation structure in a first direction. A first active pattern is disposed between the first and second gate isolation structures. The first active pattern extends longitudinally in a second direction crossing the first direction. A second active pattern is disposed between the first and second gate isolation structures. The second active pattern extends longitudinally in the second direction and is spaced apart from the first active pattern in the first direction. Gate structures are disposed between the first and second gate isolation structures. The gate structures directly contact the first and second gate isolation structures. A length of the first gate isolation structure in the second direction is greater than a length of the second gate isolation structure in the second direction.

According to an embodiment of the present disclosure, a semiconductor device includes a first gate isolation structure. A second gate isolation structure is spaced apart from the first gate isolation structure in a first direction. A first active pattern is disposed between the first and second gate isolation structures. The first active pattern extends longitudinally in a second direction crossing the first direction. A second active pattern is disposed between the first and second gate isolation structures. The second active pattern extends longitudinally in the second direction and is spaced apart from the first active pattern in the first direction. A plurality of gate structures intersects the first and second gate isolation structures and extends longitudinally in the first direction. A number of gate structures directly contacting the first gate isolation structure is greater than a number of gate structures directly contacting the second gate isolation structure.

According to an embodiment of the present disclosure, a semiconductor device includes a first gate isolation structure. A second gate isolation structure is spaced apart from the first gate isolation structure in a first direction. A first active pattern is disposed between the first and second gate isolation structures. The first active pattern includes a first lower pattern extending longitudinally in the second direction and first sheet patterns that are spaced apart from the first lower pattern in a third direction that is a thickness direction crossing the first and second directions. A second active pattern is disposed between the first and second gate isolation structures. The second active pattern includes a second lower pattern extending in the second direction and spaced apart from the first lower pattern in the first direction and second sheet patterns that are spaced apart from the second lower pattern in the third direction. Gate structures are disposed between the first and second gate isolation structures. The gate structures directly contact the first and second gate isolation structures. First source/drain patterns are disposed on the first lower pattern. The first source/drain patterns are connected to the first sheet patterns and are doped with impurities of a first conductivity type. Second source/drain patterns are disposed on the second lower pattern. The second source/drain patterns are connected to the second sheet patterns and are doped with impurities of a second conductivity type that is different from the first conductivity type. The first gate isolation structure overlaps with the first source/drain patterns and the second source/drain patterns in the first direction. The second gate isolation structure does not overlap with the first source/drain patterns and the second source/drain patterns in the first direction.

It should be noted that the effects of embodiments of the present disclosure are not limited to those described above, and other effects of embodiments the present disclosure will be apparent from the following description.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of embodiments of the present disclosure given below.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a layout view of a semiconductor device according to an embodiment of the present disclosure.

FIGS. 2, 3, 4, 5, and 6 are cross-sectional views taken along lines A-A, B-B, C-C, D-D, and E-E, respectively, of FIG. 1 according to some embodiments of the present disclosure.

FIG. 7 is a cross-sectional view of a semiconductor device according to an embodiment of the present disclosure.

FIGS. 8 through 10 are cross-sectional views of a semiconductor device according to some embodiments of the present disclosure.

FIGS. 11 through 14 are cross-sectional views of semiconductor devices according to some embodiments of the present disclosure.

FIGS. 15 and 16 are cross-sectional views of semiconductor devices according to some embodiments of the present disclosure.

FIGS. 17 through 21 illustrate a semiconductor device according to some embodiments of the present disclosure.

FIGS. 22 and 23 are drawings for explaining a semiconductor device according to some embodiments of the present disclosure.

FIGS. 24 through 31 are drawings illustrating intermediate steps of a method of manufacturing a semiconductor device according to some embodiments of the present disclosure.

### DETAILED DESCRIPTION OF EMBODIMENTS

The accompanying drawings related to semiconductor devices according to some embodiments of the present disclosure and illustrate fin-shaped field-effect transistors (FinFETs) with fin-shaped channel areas, transistors containing nano wires or nano sheets, and multi-bridge channel field-effect transistors (MBCFETs™), as examples. However, embodiments of the present disclosure are not necessarily limited to those examples.

Semiconductor devices according to some embodiments of the present disclosure may include tunneling field-effect transistors (FETs), three-dimensional (3D) transistors, or vertical FETs. Semiconductor devices according to some embodiments of the present disclosure may also include planar transistors. Furthermore, in some embodiments of the present disclosure, the features may be applied to two-dimensional (2D) material-based transistors and their heterostructures. Additionally, semiconductor devices according to some embodiments of the present disclosure may also include bipolar junction transistors, lateral diffused metal-oxide semiconductor (LDMOS) transistors, and others.

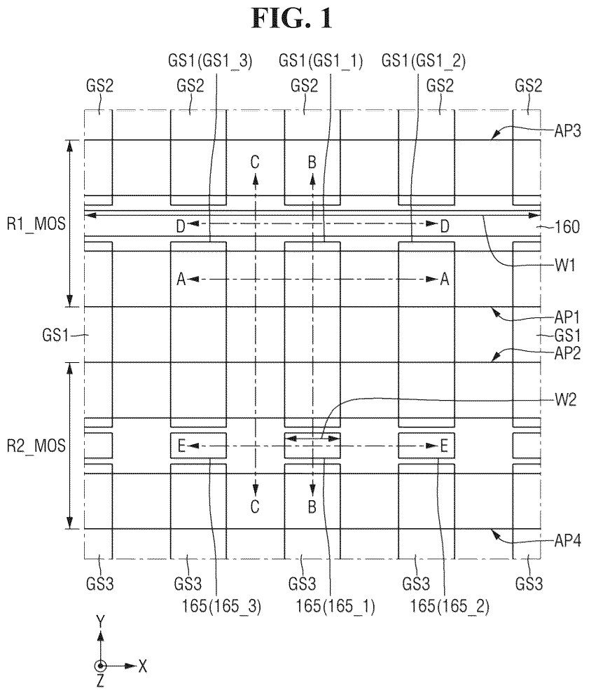

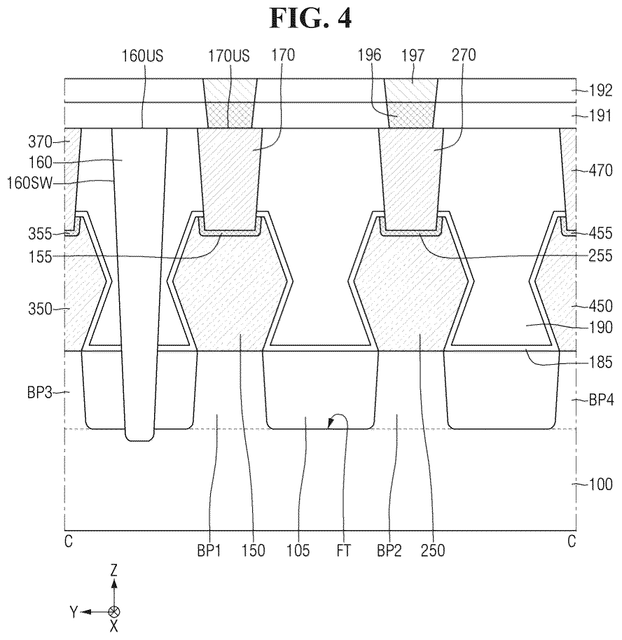

A semiconductor device according to some embodiments of the present disclosure will hereinafter be described with reference to FIGS. 1 through 6.

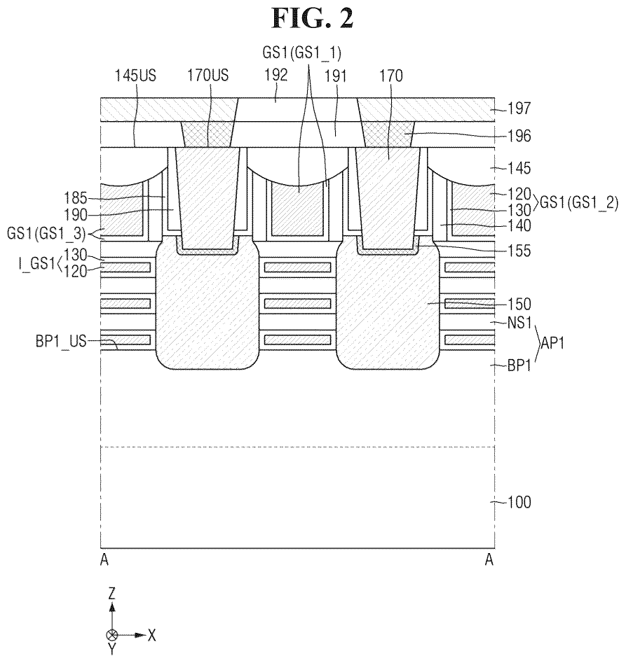

FIG. 1 is a layout view of a semiconductor device according to some embodiments of the present disclosure. FIGS. 2, 3, 4, 5, and 6 are cross-sectional views taken along lines A-A, B-B, C-C, D-D, and E-E, respectively, of FIG. 1.

For the convenience of description, FIG. 1 does not illustrate source/drain contacts (170, 270, 370, and 470), first gate contacts 175, wiring vias 196, and wiring lines 197. In an embodiment, cross-sectional views, taken along a first direction X, of second, third, and fourth active patterns AP2, AP3, and AP4 may be similar to FIG. 2.

Referring to FIGS. 1 through 6, the semiconductor device may include a first substrate 100, first, second, third, and fourth active patterns AP1, AP2, AP3, and AP4, a plurality of first gate structures GS1, a plurality of second gate structures GS2, a plurality of third gate structures GS3, first source/drain patterns 150, second source/drain patterns 250, third source/drain patterns 350, fourth source/drain patterns 450, first source/drain contacts 170, second source/drain contacts 270, third source/drain contacts 370, fourth source/drain contacts 470, a line gate isolation structure 160, point gate isolation structures 165, wiring vias 196, and wiring lines 197.

In an embodiment, the substrate 100 may include a first transistor formation region R1_MOS and a second transistor formation region R2_MOS. For example, in an embodiment the first transistor formation region R1_MOS may be a P-type metal-oxide semiconductor (PMOS) formation region, and the second transistor formation region R2_MOS may be an N-type metal-oxide semiconductor (NMOS) formation region. Alternatively, the first transistor formation region R1_MOS may be an NMOS formation region, and the second transistor formation region R2_MOS may be a PMOS formation region.

The substrate 100 may be formed of a semiconductor material or may include a semiconductor material. In an embodiment, the substrate 100 may be a silicon substrate or a silicon-on-insulator (an SOI) substrate. Alternatively, the substrate 100 may include, for example, silicon germanium, silicon germanium-insulator (SGOI), indium antimonide, a lead telluride compound, indium arsenide, indium phosphide, gallium arsenide, or gallium antimonide. However, embodiments of the present disclosure are not necessarily limited thereto.

The first, second, third, and fourth active patterns AP1, AP2, AP3, and AP4 may be disposed on the substrate 100. In an embodiment, the first, second, third, and fourth active patterns AP1, AP2, AP3, and AP4 may extend longitudinally in the first direction X.

The first active pattern AP1 may be spaced apart from the second and third active patterns AP2 and AP3 in a second direction Y. The second active pattern AP2 may be spaced apart from the fourth active pattern AP4 in the second direction Y.

For example, the first and second active patterns AP1 and AP2 may be directly adjacent to each other in the second direction Y and there may be no additional active patterns disposed between the first and second active patterns AP1 and AP2.

In an embodiment, the first and third active patterns AP1 and AP3 may be disposed in the first transistor formation region R1_MOS. The second and fourth active patterns AP2 and AP4 may be disposed in the second transistor formation region R2_MOS. For example, in an embodiment the first active pattern AP1 may be disposed in an area where P-type transistors are formed, and the second active pattern AP2 may be disposed in an area where N-type transistors are formed. Alternatively, the first active pattern AP1 may be disposed in an area where N-type transistors are formed, and the second active pattern AP2 may be disposed in an area where P-type transistors are formed

In an embodiment, the first, second, third, and fourth active patterns AP1, AP2, AP3, and AP4 may be multi-channel active patterns. For example, the first active pattern AP1 may include a first base pattern BP1 and a plurality of first sheet patterns NS1. For example, the second active pattern AP2 may include a second base pattern BP2 and a plurality of second sheet patterns NS2. For example, the third active pattern AP3 may include a third base pattern BP3 and a plurality of third sheet patterns NS3. For example, the fourth active pattern AP4 may include a fourth base pattern BP4 and a plurality of fourth sheet patterns NS4. In some embodiments, the first, second, third, and fourth active patterns AP1, AP2, AP3, and AP4 may be active patterns including nano sheets or nano wires.

The first, second, third, and fourth base patterns BP1, BP2, BP3, and BP4 may protrude from the substrate 100 (e.g., in the Z direction which is a vertical direction that is a thickness direction of the substrate 100). For example, the first, second, third, and fourth base patterns BP1, BP2, BP3, and BP4 may be fin-type patterns.

The first, second, third, and fourth base patterns BP1, BP2, BP3, and BP4 may extend longitudinally in the first direction X. The first base pattern BP1 may be spaced apart from the second and third base patterns BP2 and BP3 in the second direction Y. The second base pattern BP2 may be spaced apart from the fourth base pattern BP4 in the second direction Y.

The first, second, third, and fourth base patterns BP1, BP2, BP3, and BP4 may be separated by fin trenches FT extending in the first direction X. For example, the lower surfaces of the fin trenches FT may correspond to the upper surface of the substrate 100. Each of the first, second, third, and fourth base patterns BP1, BP2, BP3, and BP4 includes sidewalls extending longitudinally in the first direction X. The sidewalls of each of the first, second, third, and fourth base patterns BP1, BP2, BP3, and BP4 may be defined by the fin trenches FT.

A plurality of first sheet patterns NS1 may be disposed on the first base pattern BP1. The first sheet patterns NS1 may be spaced apart from a upper surface BP1_US of the first base pattern BP1 in a third direction Z. The first sheet patterns NS1 may be disposed on the upper surface of the substrate 100.

A plurality of second sheet patterns NS2 may be disposed on the second base pattern BP2. The second sheet patterns NS2 may be spaced apart from the second base pattern BP2 in the third direction Z. A plurality of third sheet patterns NS3 may be disposed on the third base pattern BP3. The third sheet patterns NS3 may be spaced apart from the third base pattern BP3 in the third direction Z. A plurality of fourth sheet patterns NS4 may be disposed on the fourth base pattern BP4. The fourth sheet patterns NS4 may be spaced apart from the fourth base pattern BP4 in the third direction Z. The second sheet patterns NS2, the third sheet patterns NS3, and the fourth sheet patterns NS4 may be disposed on the upper surface of the substrate 100.

The first direction X may intersect the second and third directions Y and Z. Also, the second direction Y may intersect the third direction Z. The third direction Z may be the thickness direction of the first substrate 100. For example, in an embodiment the first to third directions X, Y, Z may be perpendicular to each other. However, embodiments of the present disclosure are not necessarily limited thereto.

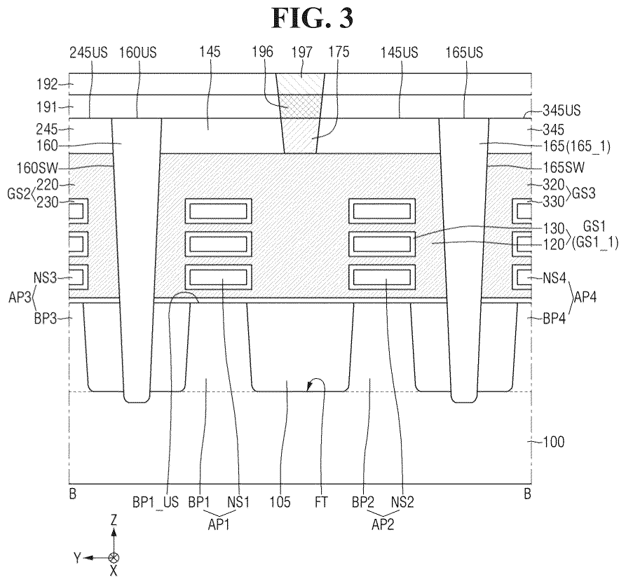

Each of sheet patterns (NS1, NS2, NS3, and NS4) may have opposing top and lower surfaces in the third direction Z. The lower surfaces of the sheet patterns (NS1, NS2, NS3, and NS4) may face the substrate 100. Three first sheet patterns NS1, three second sheet patterns NS2, three third sheet patterns NS3, and three fourth sheet patterns NS4 are illustrated in FIG. 3 as being disposed in the third direction Z. However, embodiments of the present disclosure are not necessarily limited thereto and the numbers of the plurality of first to fourth sheet patterns NS1 to NS4 may vary.

The sheet patterns (NS1, NS2, NS3, and NS4) may include uppermost first, second, third, and fourth sheet patterns NS1, NS2, NS3, and NS4 that are furthest sheet patterns from the substrate 100 (e.g., in the third direction Z). For example, in an embodiment the upper surfaces of the first, second, third, and fourth active patterns AP1, AP2, AP3, and AP4 may be the upper surfaces of the uppermost first, second, third, and fourth sheet patterns NS1, NS2, NS3, and NS4.

In an embodiment, each of the first, second, third, and fourth base patterns BP1, BP2, BP3, and BP4 may be formed by etching a portion of the substrate 100 or may include an epitaxial layer grown from the substrate 100. In an embodiment, each of the first, second, third, and fourth base patterns BP1, BP2, BP3, and BP4 may include silicon or germanium, which is an elemental semiconductor material. Additionally, each of the first, second, third, and fourth base patterns BP1, BP2, BP3, and BP4 may include a compound semiconductor, for example, a group IV-IV compound semiconductor or a group III-V compound semiconductor.

In an embodiment, the group IV-IV compound semiconductor may include, for example, a binary, ternary, or quaternary compound comprising at least two elements selected from among carbon (C), silicon (Si), germanium (Ge), and tin (Sn), or a compound obtained by doping the binary, ternary, or quaternary compound with a group IV element.

In an embodiment, the group III-V compound semiconductor may include, for example, a binary, ternary, or quaternary compound formed by combining at least one of aluminum (Al), gallium (Ga), and indium (In), which are group III elements, with one of phosphorus (P), arsenic (As), and antimony (Sb), which are group V elements.

In an embodiment, the sheet patterns (NS1, NS2, NS3, and NS4) may include either Si or Ge, which is an elemental semiconductor material, or a group IV-IV or III-V compound semiconductor. In an embodiment, the width of the sheet patterns (NS1, NS2, NS3, and NS4) (e.g., the width of the first sheet patterns NS1) in the second direction Y may increase or decrease proportionally to the width of the first base pattern BP1 in the second direction Y. Each of the first sheet patterns NS1 disposed on the first lower pattern BP1 are illustrated in FIG. 3 as having the same width as each other in the second direction Y. However, embodiments of the present disclosure are not necessarily limited thereto.

A field insulating film 105 is disposed on the substrate 100. The field insulating film 105 may fill at least portions of the fin trenches FT that separate the first, second, third, and fourth base patterns BP1, BP2, BP3, and BP4 from each other.

The field insulating film 105 may be disposed on the substrate 100 between the first, second, third, and fourth base patterns BP1, BP2, BP3, and BP4. For example, in an embodiment the field insulating film 105 may cover the entirety of sidewalls of the first, second, third, and fourth base patterns BP1, BP2, BP3, and BP4. Alternatively, in an embodiment, the field insulating film 105 may cover only portions of the sidewalls of the first, second, third, and fourth base patterns BP1, BP2, BP3, and BP4. In this embodiment, portions of the first, second, third, and fourth base patterns BP1, BP2, BP3, and BP4 may protrude beyond the upper surface of the field insulating film 105 in the third direction Z.

The field insulating film 105 does not cover the upper surface BP1_US of the first base pattern BP1. The field insulating film 105 does not cover the upper surfaces of the second, third, and fourth base patterns BP2, BP3, and BP4. In an embodiment, the upper surface of the substrate 100, the first, second, third, and fourth base patterns BP1, BP2, BP3, and BP4 are positioned higher (e.g., in the third direction Z) than the upper surface of the field insulating film 105.

In an embodiment, the field insulating film 105 may include, for example, an oxide layer, a nitride layer, an oxynitride layer, or a combination thereof. The field insulating film 105 is illustrated as being a single layer. However, embodiments of the present disclosure are not necessarily limited thereto.

A plurality of first gate structures GS1 may be disposed on the substrate 100. In an embodiment, the first gate structures GS1 may extend longitudinally in the second direction Y. The first gate structures GS1 may be spaced apart from one another in the first direction X.

The first gate structures GS1 may be disposed on (e.g., disposed directly thereon) the first and second active patterns AP1 and AP2. The first gate structures GS1 may intersect the first and second active patterns AP1 and AP2.

The first gate structures GS1 may intersect the first and second base patterns BP1 and BP2. The first gate structures GS1 may surround each of the first sheet patterns NS1. The first gate structures GS1 may surround each of the second sheet patterns NS2.

A plurality of second gate structures GS2 may be disposed on the substrate 100. Each of the second gate structures GS2 may extend longitudinally in the second direction Y. The second gate structures GS2 may be spaced apart from one another in the first direction X. The second gate structures GS2 may be spaced apart from the first gate structures GS1 in the second direction Y. In an embodiment, the first gate structures GS1 and the second gate structures GS2 may be aligned with one another in the second direction Y.

The second gate structures GS2 may be disposed on (e.g., disposed directly thereon) the third active pattern AP3. The second gate structures GS2 may intersect the third active pattern AP3. The second gate structures GS2 may intersect the third base pattern BP3. The second gate structures GS2 may surround each of the third sheet patterns NS3.

A plurality of third gate structures GS3 may be disposed on (e.g., disposed directly thereon) the substrate 100. The third gate structures GS3 may extend in the second direction Y. The third gate structures GS3 may be spaced apart from one another in the first direction X. The third gate structures GS3 may be spaced apart from the first gate structures GS1 in the second direction Y. In an embodiment, the first gate structures GS1 and the third gate structures GS3 may be aligned with one another in the second direction Y.

The third gate structures GS3 may be disposed on (e.g., disposed directly thereon) the fourth active pattern AP4. The third gate structures GS3 may intersect the fourth active pattern AP4. The third gate structures GS3 may intersect the fourth base pattern BP4. The third gate structures GS3 may surround each of the fourth sheet patterns NS4.

The first gate structures GS1 may include first gate electrodes 120 and first gate insulating films 130. The second gate structures GS2 may include second gate electrodes 220 and second gate insulating films 230. The third gate structures GS3 may include third gate electrodes 320 and third gate insulating films 330.

Gate structures, such as the first to third gate structures GS1, GS2, and GS3, will hereinafter be described, taking the first gate structures GS1 an example. The first gate structures GS1 may include a plurality of first inner gate structures I_GS1, which are disposed between the first sheet patterns NS1 adjacent to each other in the third direction Z and between the first base pattern BP1 and the first sheet patterns NS1 which are adjacent to each other in the third direction Z. For example, the first inner gate structures I_GS1 may be disposed between the upper surface BP1_US of the first base pattern BP1 and the lower surfaces of the first sheet patterns NS1 and between the opposing top and lower surfaces of each pair of adjacent first sheet patterns NS1 in the third direction Z.

The number of first inner gate structures I_GS1 may be equal to the number of first sheet patterns NS1. The first inner gate structures I_GS1 may directly contact the upper surface BP1_US of the first base pattern BP1 and the upper surfaces and lower surfaces of the first sheet patterns NS1. In some embodiments, the first inner gate structures I_GS1 may directly contact the first source/drain patterns 150, which will be described later.

In an embodiment, the first inner gate structures I_GS1 may include the first gate electrodes 120 and first gate insulating films 130, which are disposed between the first sheet patterns NS1 adjacent in the third direction Z and between the first base pattern BP1 and the first sheet patterns NS1. In an embodiment, the first inner gate structures I_GS1 may be disposed between the second sheet patterns NS2 adjacent in the third direction Z and between the second base pattern BP2 and the second sheet patterns NS2 in the third direction Z.

In an embodiment, the second gate structures GS2 may include second inner gate structures, which are disposed between the third sheet patterns NS3 adjacent in the third direction Z and between the third base pattern BP3 and the third sheet patterns NS3 in the third direction Z. The third gate structures GS3 may include third inner gate structures, which are disposed between adjacent fourth sheet patterns NS4 in the third direction Z and between the fourth base pattern BP4 and the fourth sheet patterns NS4 in the third direction Z.

The first gate electrodes 120 may be disposed on (e.g., disposed directly thereon) the first and second base patterns BP1 and BP2. The first gate electrodes 120 may intersect the first and second base patterns BP1 and BP2. The first gate electrodes 120 may surround the first sheet patterns NS1 and the second sheet patterns NS2.

In a cross-sectional view such as FIG. 2, the upper surfaces of the first gate electrodes 120 are illustrated as being concave surfaces. However, embodiments of the present disclosure are not necessarily limited thereto. Alternatively, the upper surfaces of the first gate electrodes 120 may be relatively flat.

The second gate electrodes 220 may be disposed on (e.g., disposed directly thereon) the third base pattern BP3. The second gate electrodes 220 may intersect the third base pattern BP3. The second gate electrodes 220 may surround the third sheet patterns NS3. The third gate electrodes 320 may be disposed on the fourth base pattern BP4. The third gate electrodes 320 may intersect the fourth base pattern BP4. The third gate electrodes 320 may surround the fourth sheet patterns NS4.

The gate electrodes, such as the first to third gate electrodes 120, 220, and 320 may include at least one of a metal, a metal alloy, a conductive metal nitride, a metal silicide, a doped semiconductor material, a conductive metal oxide, and a conductive metal oxynitride. In an embodiment, the gate electrodes, such as the first to third gate electrodes 120, 220, and 320, may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TIC), tantalum carbonitride (TaCN), tungsten (W), Al, copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. However, embodiments of the present disclosure are not necessarily limited thereto. In an embodiment, the conductive metal oxide and conductive metal oxynitride may include oxidized forms of the aforementioned materials. However, embodiments of the present disclosure are not necessarily limited thereto.

In an embodiment, the first gate insulating films 130 may extend along the upper surface of the field insulating film 105, the upper surface BP1_US of the first base pattern BP1, and the upper surface of the second base pattern BP2. The first gate insulating films 130 may surround the first sheet patterns NS1. The first gate insulating films 130 may surround the second sheet patterns NS2.

The first gate electrodes 120 may be disposed on (e.g., disposed directly thereon) the first gate insulating films 130. The first gate insulating films 130 may be disposed between the first gate electrodes 120 and the first sheet patterns NS1, and between the first gate electrodes 120 and the second sheet patterns NS2. In some embodiments, the first gate insulating films 130 included in the first inner gate structures I_GS1 may directly contact the first source/drain patterns 150, which will be described later.

In an embodiment, the second gate insulating films 230 may extend along the upper surface of the field insulating film 105 and the upper surface of the third base pattern BP3. The second gate insulating films 230 may surround the third sheet patterns NS3. The second gate insulating films 230 may be disposed between the second gate electrodes 220 and the third sheet patterns NS3.

The third gate insulating films 330 may extend along the upper surface of the field insulating film 105 and the upper surface of the fourth base pattern BP4. The third gate insulating films 330 may surround the fourth sheet patterns NS4. The third gate insulating films 330 may be disposed between the third gate electrodes 320 and the fourth sheet patterns NS4.

In an embodiment, the gate insulating films, such as the first to third gate insulating films 130, 230, and 330, may include silicon oxide, silicon oxynitride, silicon nitride, or a high-k dielectric material with a greater dielectric constant than silicon oxide. The high-k dielectric material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. However, embodiments of the present disclosure are not necessarily limited thereto.

The gate insulating films, such as the first to third gate insulating films 130, 230, and 330, are illustrated as being single films. However, embodiments of the present disclosure are not necessarily limited thereto. The gate insulating films, such as the first to third gate insulating films 130, 230, and 330, will hereinafter be described, taking the first gate insulating films 130 as an example. In an embodiment, each of the first gate insulating films 130 may include multiple films. For example, in an embodiment the first gate insulating films 130 may include interfacial films and high-k insulating films disposed between the first active pattern AP1 and the first gate electrodes 120, and between the second active patterns AP2 and the first gate electrodes 120. For example, the interfacial films may not be formed along the profile of the upper surface of the field insulating film 105.

In an embodiment, the semiconductor device may include a negative capacitance field-effect transistor (NCFET) utilizing a negative capacitor. For example, each of the gate insulating films, such as the first to third gate insulating films 130, 230, and 330, may include a ferroelectric material film with ferroelectric properties and a paraelectric material film with paraelectric properties.

The ferroelectric material film may have negative capacitance, and the paraelectric material film may have positive capacitance. For example, in an embodiment in which two or more capacitors are connected in series, and each of the capacitors has a positive capacitance, the total capacitance of the capacitors is reduced compared to the capacitance of each of the capacitors. Conversely, if at least one of the capacitors has a negative capacitance, the total capacitance of the capacitors may have a positive value and may be greater than the absolute value of the capacitance of each of the capacitors.

In an embodiment in which a ferroelectric material film with a negative capacitance and a paraelectric material film with a positive capacitance are connected in series, the total capacitance of the ferroelectric and paraelectric material films may increase. In an embodiment, utilizing this capacitance increase, the transistor including the ferroelectric material film can have a subthreshold swing (SS) of about 60 mV/decade or less at room temperature.

The ferroelectric material film may have ferroelectric properties. For example, in an embodiment the ferroelectric material film may include at least one of hafnium oxide, hafnium zirconium oxide, barium strontium titanium oxide, barium titanium oxide, and lead zirconium titanium oxide. In an embodiment, the hafnium zirconium oxide may be, for example, a material obtained by doping hafnium oxide with zirconium (Zr). Alternatively, the hafnium zirconium oxide may be the compound of hafnium (Hf), Zr, and oxygen (O).

In an embodiment, the ferroelectric material film may further include a dopant. For example, in an embodiment the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and Sn. The type of the dopant included in the ferroelectric material film may vary depending on the type of the ferroelectric material included in the ferroelectric material film.

In an embodiment in which the ferroelectric material film includes hafnium oxide, the dopant included in the ferroelectric material film may include at least one of Gd, Si, Zr, Al, and Y.

In an embodiment in which the dopant is Al, the ferroelectric material film may contain about 3 to about 8 atomic % (at %) of Al. Here, the proportion of the dopant may be the ratio of Al to the sum of Hf and Al.

In an embodiment in which the dopant is Si, the ferroelectric material film may contain about 2 to about 10 at % of Si. In an embodiment in which the dopant is Y, the ferroelectric material film may contain about 2 to about 10 at % of Y. In an embodiment in which the dopant is Gd, the ferroelectric material film may contain about 1 to about 7 at % of Gd. In an embodiment in which the dopant is Zr, the ferroelectric material film may contain about 50 to about 80 at % of Zr.

The paraelectric material film may have paraelectric properties. For example, in an embodiment the paraelectric material film may include at least one of silicon oxide and a high-k metal oxide. In an embodiment, the high-k metal oxide may include at least one of hafnium oxide, zirconium oxide, and aluminum oxide. However, embodiments of the present disclosure are not necessarily limited thereto.

In an embodiment, the ferroelectric material film and the paraelectric material film may include the same material as each other. The ferroelectric material film may have ferroelectric properties, but the paraelectric material film may not have ferroelectric properties. For example, in an embodiment in which both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, in an embodiment the thickness of the ferroelectric material film may be in a range of about 0.5 nm to about 10 nm. However, embodiments of the present disclosure are not necessarily 8 limited thereto. Since the critical thickness for exhibiting ferroelectric properties may vary from one ferroelectric material to another, the thickness of the ferroelectric material film may vary depending on its material.

For example, each of the gate insulating films, such as the first to third gate insulating films 130, 230, and 330, may include one ferroelectric material film. Alternatively, each of the gate insulating films, such as the first to third gate insulating films 130, 230, and 330, may include a plurality of ferroelectric material films that are spaced apart from one another. Each of the gate insulating films, such as the first to third gate insulating films 130, 230, and 330, may have a layered film structure in which a plurality of ferroelectric material films and a plurality of paraelectric material films are alternately stacked (e.g., in the third direction Z).

In an embodiment, first gate spacers 140 may be disposed on the sidewalls of the first gate structures GS1. The first gate spacers 140 may not be disposed between the first base pattern BP1 and the first sheet patterns NS1, and between the first sheet patterns NS1 adjacent in the third direction D3. In an embodiment, second gate spacers may be disposed on the sidewalls of the second gate structures GS2, and third gate spacers may be disposed on the sidewalls of the third gate structures GS3.

In an embodiment, the first gate spacers 140 may include, for example, at least one of silicon nitride (SiN), silicon oxynitride (SiON), silicon dioxide (SiO₂), silicon oxycarbonitride (SiOCN), silicon boron nitride (SiBN), silicon oxyboron nitride (SiOBN), silicon oxycarbide (SiOC), and a combination thereof. The first gate spacers 140 are illustrated as being single films. However, embodiments of the present disclosure are not necessarily limited thereto.

First gate capping patterns 145 may be disposed on (e.g., disposed directly thereon in the third direction Z) the first gate electrodes 120. Alternatively, the first gate capping pattern 145 may be disposed between the first gate spacers 140.

Second gate capping patterns 245 may be disposed on (e.g., disposed directly thereon in the third direction Z) the second gate electrodes 220. The third gate capping pattern 345 may be disposed on (e.g., disposed directly thereon in the third direction Z) the third gate electrodes 320.

In an embodiment, gate capping patterns, such as the first to third gate capping patterns 145, 245, and 345, may include, for example, at least one of SiN, SiON, silicon carbonitride (SiCN), SiOCN, and a combination thereof.

In an embodiment, the first source/drain patterns 150 may be disposed on (e.g., disposed directly thereon) the first active pattern AP1. The first source/drain patterns 150 may be disposed on (e.g., disposed directly thereon) the first base pattern BP1. The first source/drain patterns 150 may be disposed between the first gate electrodes 120 adjacent in the first direction X. The first source/drain patterns 150 may directly contact the first active pattern AP1. The first source/drain patterns 150 may directly contact the first sheet patterns NS1. The first source/drain patterns 150 are connected to the first sheet patterns NS1 and the first base pattern BP1.

In an embodiment, the second source/drain patterns 250 may be disposed on (e.g., disposed directly thereon) the second active pattern AP2. The second source/drain patterns 250 may also be disposed on (e.g., disposed directly thereon) the second base pattern BP2. The second source/drain patterns 250 may be disposed between the first gate electrodes 120 adjacent in the first direction X. The second source/drain patterns 250 may directly contact the second active pattern AP2. In an embodiment, the second source/drain patterns 250 may directly contact the second sheet patterns NS2. The second source/drain patterns 250 are connected to the second sheet patterns NS2 and the second base pattern BP2.

In an embodiment, the third source/drain patterns 350 may be disposed on (e.g., disposed directly thereon) the third active pattern AP3. The third source/drain patterns 350 may also be disposed on (e.g., disposed directly thereon) the third base pattern BP3. The third source/drain patterns 350 may be disposed between second gate electrodes 220 adjacent in the first direction X. In an embodiment, the third source/drain patterns 350 may directly contact the third sheet patterns NS3.

The fourth source/drain patterns 450 may be disposed on (e.g., disposed directly thereon) the fourth active pattern AP4. The fourth source/drain patterns 450 may also be disposed on (e.g., disposed directly thereon) the fourth base pattern BP4. The fourth source/drain patterns 450 may be disposed between third gate electrodes 320 adjacent in the first direction X. In an embodiment, the fourth source/drain patterns 450 may directly contact the fourth sheet patterns NS4.

In an embodiment, each of source/drain patterns, such as the first to fourth source/drain patterns 150, 250, 350, and 450, may include a lower surface facing the first, second, third, or fourth base pattern BP1, BP2, BP3, or BP4 and sidewalls extending from the lower surface in the third direction Z. In an embodiment, the sidewalls of the source/drain patterns, such as the first to fourth source/drain patterns 150, 250, 350, and 450, may include faceted intersections where slopes meet. However, embodiments of the present disclosure are not necessarily limited thereto.

The first source/drain patterns 150 may be included in the source/drain of a transistor using the first sheet patterns NS1 as a channel area. The second source/drain patterns 250 may be included in the source/drain of a transistor using the second sheet patterns NS2 as a channel area. The third source/drain patterns 350 may be included in the source/drain of a transistor using the third sheet patterns NS3 as a channel area. The fourth source/drain patterns 450 may be included in the source/drain of a transistor using the fourth sheet patterns NS2 as a channel area.

In an embodiment, each of the source/drain patterns, such as the first to fourth source/drain patterns 150, 250, 350, and 450, may include an epitaxial pattern. The source/drain patterns, such as the first to fourth source/drain patterns 150, 250, 350, and 450, may include a semiconductor material.

In an embodiment in which the first transistor formation region R1_MOS is a PMOS formation region, the first source/drain patterns 150 and the third source/drain patterns 350 may include a p-type dopant. The second source/drain patterns 250 and the fourth source/drain patterns 450 may include an n-type dopant. In an embodiment, the p-type dopant may include at least one of boron (B) and Ga. However, embodiments of the present disclosure are not necessarily limited thereto. In an embodiment, the n-type dopant may include at least one of P, As, Sb, and bismuth (Bi). However, embodiments of the present disclosure are not necessarily limited thereto.

In an embodiment in which the first transistor formation region R1_MOS is an NMOS formation region, the first source/drain patterns 150 and the third source/drain patterns 350 may include an n-type dopant. The second source/drain patterns 250 and the fourth source/drain patterns 450 may include a p-type dopant.

In an embodiment, source/drain etch stop films 185 may extend along the outer walls of the first gate spacers 140 and along the sidewalls of the source/drain patterns, such as the first to fourth source/drain patterns 150, 250, 350, and 450. The source/drain etch stop films 185 may also extend along the upper surface of the field insulating film 105.

The source/drain etch stop films 185 may not extend along the sidewalls of the first gate capping patterns 145. Alternatively, the source/drain etch stop films 185 may also extend along the sidewalls of the first gate capping patterns 145.

In an embodiment, the source/drain etch stop films 185 may include, for example, at least one of SiN, SiON, SIOCN, SiBN, SIOBN, SiOC, or a combination thereof.

In an embodiment, a first interlayer insulating film 190 may be disposed on the field insulating film 105. In an embodiment, the first interlayer insulating film 190 may also be disposed on the source/drain patterns, such as the first to fourth source/drain patterns 150, 250, 350, and 450.

In an embodiment, the first interlayer insulating film 190 may not cover upper surfaces 145US of the first gate capping patterns 145. In an embodiment, the first interlayer insulating film 190 may not cover upper surfaces 245US of the second gate capping patterns 145 and upper surfaces 345US of the third gate capping patterns 345.

In an embodiment, the first interlayer insulating film 190 may include, for example, at least one of silicon oxide, silicon nitride, silicon oxynitride, and a low-k dielectric material. The dielectric constant of the low-k dielectric material may be less than 3.9, which is the dielectric constant of silicon oxide.

In an embodiment, the first source/drain contacts 170 may be disposed on the first source/drain patterns 150. The first source/drain contacts 170 are electrically connected to the first source/drain patterns 150.

In an embodiment, the second source/drain contacts 270 may be disposed on the second source/drain patterns 250. The second source/drain contacts 270 are electrically connected to the second source/drain patterns 250.

The first source/drain contacts 170 are illustrated as being spaced apart from the second source/drain contacts 270 in the second direction Y. However, embodiments of the present disclosure are not necessarily limited thereto. Alternatively, in an embodiment, single connected source/drain contacts may be formed on both the first source/drain patterns 150 and the second source/drain patterns 250. The connected source/drain contacts may be electrically connected to both the first source/drain patterns 150 and the second source/drain patterns 250.

In an embodiment, the third source/drain contacts 370 may be disposed on the third source/drain patterns 350. The third source/drain contacts 370 are electrically connected to the third source/drain patterns 350.

In an embodiment, the fourth source/drain contacts 470 may be disposed on the fourth source/drain patterns 450. The fourth source/drain contacts 470 are electrically connected to the fourth source/drain patterns 450.

The source/drain contacts, such as the first to fourth source/drain contacts 170, 270, 370, and 470, may be disposed within the first interlayer insulating film 190. The source/drain contacts, such as the first to fourth source/drain contacts 170, 270, 370, and 470, will hereinafter be described, taking the first source/drain contacts 170 as an example. The first interlayer insulating film 190 does not cover upper surfaces 170US of the first source/drain contacts 170. For example, in an embodiment based on the upper surface of the substrate 100, the height of the upper surfaces 170US of the first source/drain contacts 170 may be the same as the height of the upper surfaces 145US of the first gate capping patterns 145. For example, the upper surfaces of the first source/drain contacts 170US and the first capping patterns 145US may be coplanar in the third direction Z.

In an embodiment, first contact silicide films 155 may be disposed between the first source/drain contacts 170 and the first source/drain patterns 150. Second contact silicide films 255 may be disposed between the second source/drain contacts 270 and the second source/drain patterns 250. Third contact silicide films 355 may be disposed between the third source/drain contacts 370 and the third source/drain patterns 350. Fourth contact silicide films 455 may be disposed between the fourth source/drain contacts 470 and the fourth source/drain patterns 450.

The first to fourth source/drain contacts are illustrated as having a single conductive layer structure. However, embodiments of the present disclosure are not necessarily limited thereto. Alternatively, in an embodiment the first to fourth source/drain contacts 170, 270, 370, and 470 may have a multi-conductive layer structure including barrier films and plug films. In an embodiment, the first to fourth source/drain contacts 170, 270, 370, and 470 may include, for example, at least one of a metal, a conductive metal nitride, a conductive metal carbide, a conductive metal oxide, a conductive metal carbonitride, and a 2D material. In an embodiment, contact silicide films, such as first to fourth contact silicide films 155, 255, 355, and 455, may include a metal silicide material.

In an embodiment, the 2D material may include a 2D allotrope or compound. For example, in an embodiment the 2D material may include at least one of graphene, boron nitride (BN), molybdenum sulfide, molybdenum selenide, tungsten sulfide, tungsten selenide, and tantalum sulfide. However, embodiments of the present disclosure are not necessarily limited thereto and the 2D material may vary.

In an embodiment, the line gate isolation structure 160 (e.g., a first gate isolation structure) may be disposed on (e.g., disposed directly thereon) the substrate 100. The line gate isolation structure 160 may be disposed within the first interlayer insulating film 190 and the field insulating film 105. The line gate isolation structure 160 may directly contact the first interlayer insulating film 190 and the field insulating film 105. A portion of the line gate isolation structure 160 may be disposed within the substrate 100. However, embodiments of the present disclosure are not necessarily limited thereto.

For example, in an embodiment the line gate isolation structure 160 may be spaced apart from the substrate 100. A portion of the field insulating film 105 may be disposed between the line gate isolation structure 160 and the substrate 100.

In an embodiment, the line gate isolation structure 160 may be disposed in the first transistor formation region R1_MOS. The line gate isolation structure 160 may be disposed between the first active pattern AP1 and the third active patterns AP3 (e.g., in the second direction Y).

The line gate isolation structure 160 may separate the first gate structures GS1 and the second gate structures GS2 that are adjacent to the first gate structures GS1 in the second direction Y. In an embodiment, the first gate structures GS1 and the second gate structures GS2 may directly contact the line gate isolation structure 160.

The line gate isolation structure 160 may separate the first gate capping patterns 145 and the second gate capping patterns 245 from each other (e.g., in the second direction Y). For example, an upper surface 160US of the line gate isolation structure 160 may be on the same plane (e.g., in the third direction Z) as the upper surfaces 145US of the first gate capping patterns 145 and the upper surfaces 245US of the second gate capping patterns 245.

A plurality of point gate isolation structures 165 (e.g., second gate isolation structures) may be disposed on the substrate 100. The point gate isolation structures 165 may be spaced apart from one another in the first direction X. The point gate isolation structures 165 may be disposed between the first gate spacers 140. For example, the point gate isolation structures 165 may be disposed between the first gate spacers 140 that extend in the second direction Y along the sidewalls of the first gate structures GS1.

The point gate isolation structures 165 may be disposed within the field insulating film 105. The point gate isolation structures 165 may directly contact both the field insulating film 105 and the first gate spacers 140. For example, the point gate isolation structures 165 may directly contact the inner sidewalls of the first gate spacers 140 that extend in the second direction Y. The inner sidewalls of the first gate spacers 140 that extend in the second direction Y may face the first gate structures GS1.

Portions of the point gate isolation structures 165 may be disposed within the substrate 100. Alternatively, the point gate isolation structures 165 may be spaced apart from the substrate 100. A portion of the field insulating film 105 may be disposed between the point gate isolation structures 165 and the substrate 100.

In an embodiment, each of the point gate isolation structures 165 may include an upper portion 165UP and a lower portion 165BP. The upper portion 165UP may be disposed on the lower portion 165BP (e.g., in the third direction Z).

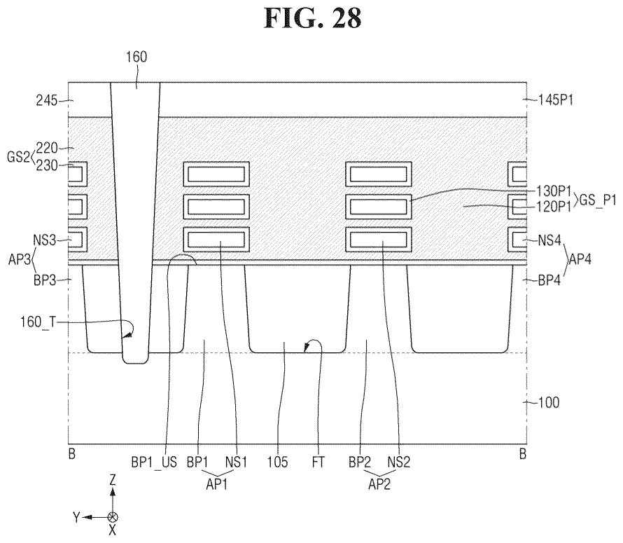

In an embodiment, the upper portions 165UP of the point gate isolation structures 165 may be formed at locations where pre-gate capping patterns 145P1 (of FIG. 28) are removed during the manufacture of the semiconductor device. The upper portions 165UP may be disposed on the first gate spacers 140 and the source/drain etch stop films 185. The upper portions 165UP may directly contact the upper surfaces of the first gate spacers 140.

The lower portions 165BP of the point gate isolation structures 165 may be disposed between the first gate spacers 140. The lower portions 165BP may be disposed within field insulating film 105.

Alternatively, in an embodiment the point gate isolation structures 165 may not include the lower portions 165BP. For example, the point gate isolation structures 165 may extend downwardly to the substrate 100 and may have the width of the upper portions 165UP in the first direction X.

In an embodiment, the point gate isolation structures 165 may be disposed in the second transistor formation region R2_MOS. The point gate isolation structures 165 may be disposed between the second and fourth active patterns AP2 and AP4.

The point gate isolation structures 165 may separate the first gate structures GS1 and the third gate structure GS3 that are adjacent to the first gate structures GS1 in the second direction Y. The first gate structures GS1 and the third gate structures GS3 may directly contact the point gate isolation structures 165.

The point gate isolation structures 165 may separate the first gate capping patterns 145 and the third gate capping patterns 345 from each other (e.g., in the second direction Y). For example, in an embodiment upper surfaces 165US of the point gate isolation structures 165 may be on the same plane (e.g., in the third direction Z) as the upper surfaces 145US of the first gate capping patterns 145 and the upper surfaces 345US of the third capping patterns 345.

In an embodiment, the first and second active patterns AP1 and AP2 may be disposed between the line gate isolation structure 160 and the point gate isolation structures 165 (e.g., in the second direction Y). In an embodiment, the first active pattern AP1 may be closer than the second active pattern AP2 to the line gate isolation structure 160. The second active pattern AP2 may be closer than the first active pattern AP1 to the first gate isolation structures 165.

In an embodiment, the first gate structures GS1 may be disposed between the line gate isolation structure 160 and the point gate isolation structures 165 (e.g., in the second direction Y). The first gate structures GS1 may directly contact sidewalls 160SW of the line gate isolation structure 160 and sidewalls 165SW of the point gate isolation structure 165.

In some embodiments, the first gate electrodes 120 and the second gate electrodes 220 may directly contact the sidewalls 160SW of the line gate isolation structure 160. The first gate electrodes 120 and the third gate electrodes 320 may directly contact the sidewalls 165SW of the point gate isolation structures 165.

In an embodiment, in a cross-sectional view such as in FIG. 3, the first gate insulating films 130 and the second gate insulating films 230 may not extend along the sidewalls 160SW of the line gate isolation structure 160. The first gate insulating films 130 and the third gate insulating films 330 may not extend along the sidewalls 165SW of the point gate isolation structures 165.

In an embodiment, the line gate isolation structure 160 may be in the form of a line extending longitudinally in the first direction X. The point gate isolation structures 165 may be in the form of contacts positioned where the first gate structures GS1 and the third gate structures GS3 are disposed and the point gate isolation structures 165 may extend between the first and third gate structures GS1, GS3.

In an embodiment, a length W1 of the line gate isolation structure 160 in the first direction X may be greater than a length W2 of the point gate isolation structures 165 in the first direction X. FIG. 1 illustrates that the line gate isolation structure 160 divides five gate structures. However, embodiments of the present disclosure are not necessarily limited thereto. The line gate isolation structure 160 may separate all gate structures included in a single standard cell, or may separate all gate structures included in multiple standard cells. For example, in an embodiment, in a layout view such as FIG. 1, the length W1 of the line gate isolation structure 160 in the first direction X may be illustrated to have its maximum possible extent.

The number of first gate structures GS1 directly contacting the line gate isolation structure 160 is greater than the number of first gate structures GS1 directly contacting the point gate isolation structures 165. For example, in an embodiment the number of first gate structures GS1 directly contacting a single line gate isolation structure 160 is greater than the number of first gate structures GS directly contacting a single point gate isolation structure 165.

In an embodiment, a single line gate isolation structure 160 may divide multiple first gate structures GS1. A single point gate isolation structure 165 may divide a single first gate structure GS1. For example, in an embodiment, one point gate isolation structure 165 may be in direct contact with only one first gate structure GS1.

In an embodiment, the first gate structures GS1 may include first, second, and third sub-gate structures GS1_1, GS1_2, and GS1_3, which are spaced apart from one another in the first direction X. The point gate isolation structures 165 may include first, second, and third point gate isolation structures 165_1, 165_2, and 165_3, which are also spaced apart from one another in the first direction X.

As shown in FIG. 1, the first sub-gate structure GS1_1 may be disposed between the line gate isolation structure 160 and the first point gate isolation structure 165_1 (e.g., in the second direction Y). The second sub-gate structure GS1_2 may be disposed between the line gate isolation structure 160 and the second point gate isolation structure 165_2 (e.g., in the second direction Y). The third sub-gate structure GS1_3 may be disposed between the line gate isolation structure 160 and the third point gate isolation structure 165_3 (e.g., in the second direction Y).

In an embodiment, the line gate isolation structure 160 may directly contact the first, second, and third sub-gate structures GS1_1, GS1_2, and GS1_3. In an embodiment, the first point gate isolation structure 165_1 directly contacts the first sub-gate structure GS1_1 but does not directly contact the second and third sub-gate structures GS1_2 and GS1_3. The second point gate isolation structure 165_2 directly contacts the second sub-gate structure GS1_2 but does not directly contact the first and third sub-gate structures GS1_1 and GS1_3. The third point gate isolation structure 165_3 directly contacts the third sub-gate structure GS1_3 but does not directly contact the first and second sub-gate structures GS1_1 and GS1_2.

As the line gate isolation structure 160 divides each of the first gate structures GS1, the first source/drain patterns 150 and the second source/drain patterns 250 may overlap with the line gate isolation structure 160 in the second direction Y. As each of the point gate isolation structures 165 divides only one first gate structure GS1, the first source/drain patterns 150 and the second source/drain patterns 250 do not overlap with the point gate isolation structures 165 in the second direction Y.

In an embodiment, the line gate isolation structure 160 and the point gate isolation structures 165 may include at least one of SiN, SiON, SiO₂, SiOCN, SiBN, SiOBN, SiOC, aluminum oxide (AlO), and a combination thereof. However, embodiments of the present disclosure are not necessarily limited thereto.

For example, in an embodiment the first transistor formation region R1_MOS may be a PMOS formation region, and the second transistor formation region R2_MOS may be an NMOS formation region. In an embodiment, the line gate isolation structure 160 and the point gate isolation structures 165 may include a material that exhibits tensile stress characteristics. In some embodiments, the line gate isolation structure 160 and the point gate isolation structures 165 may include the same material as each other. For example, in an embodiment both the line gate isolation structure 160 and the point gate isolation structures 165 may include silicon nitride. However, embodiments of the present disclosure are not necessarily limited thereto.

In an embodiment, the first transistor formation region R1_MOS may be an NMOS formation region, and the second transistor formation region R2_MOS may be a PMOS formation region. The line gate isolation structure 160 and the point gate isolation structures 165 may include a material having compressive stress characteristics. In some embodiments, the line gate isolation structure 160 and the point gate isolation structures 165 may include the same material as each other. For example, in an embodiment both the line gate isolation structure 160 and the point gate isolation structures 165 may include silicon nitride. However, embodiments of the present disclosure are not necessarily limited thereto.

Even though the same material films are disposed on the substrate 100, the stress characteristics of the material films may vary depending on how they are deposited.

In an embodiment, the first gate contacts 175 are disposed on the first gate electrodes 120. The first gate contacts 175 are connected to the first gate electrodes 120. The first gate contacts 175 may be disposed within the first gate capping patterns 145.

In an embodiment, second gate contacts, connected to the second gate electrodes 220, may be disposed on the upper surfaces of the second gate electrodes 220. Similarly, third gate contacts, connected to the third gate electrodes 320 may be disposed on the upper surfaces of the third gate electrodes 320.

The first gate contacts 175 are illustrated as having a single conductive layer structure. However, embodiments of the present disclosure are not necessarily limited thereto.

In an embodiment, the first gate contact 175 may include, for example, at least one of a metal, a conductive metal nitride, a conductive metal carbide, a conductive metal oxide, a conductive metal carbonitride, and a 2D material.

In an embodiment, the second interlayer insulating film 191 may be disposed on the first to fourth source/drain contacts 170, 270, 370, and 470 and the first to third gate capping patterns 145, 245, and 345. The third interlayer insulating film 192 may be disposed on the second interlayer insulating film 191. In an embodiment, the second and third interlayer insulating films 191 and 192 may include at least one of silicon oxide, silicon nitride, silicon oxynitride, and a low-k dielectric material.

The wiring vias 196 may be disposed within the second interlayer insulating film 191. The wiring vias 196 may be connected to (e.g., directly connected thereto in the third direction Z) the first to fourth source/drain contacts 170, 270, 370, and 470. The wiring vias 196 may also be connected to (e.g., directly connected thereto in the third direction Z) the first gate contacts 175.

The wiring lines 197 may be disposed within the third interlayer insulating film 192. The wiring lines 197 may be connected to (e.g., directly connected thereto in the third direction Z) the wiring vias 196. The wiring lines 197 may be connected to (e.g., electrically connected thereto) the first to fourth source/drain contacts 170, 270, 370, and 470 through the wiring vias 196. The wiring lines 197 may be connected to (e.g., electrically connected thereto) the first gate contacts 175 through the wiring vias 196. Alternatively, in an embodiment the wiring lines 197 may be directly connected to the first gate contacts 175. In this embodiment, the first gate contacts 175 may extend to be disposed within the second interlayer insulating film 191 as well as within the first gate capping patterns 145.

The wiring vias 196 and the wiring lines 197 are both illustrated as having a single conductive layer structure. However, embodiments of the present disclosure are not necessarily limited thereto. In an embodiment, the wiring vias 196 and the wiring lines 197 may include, for example, at least one of a metal, a conductive metal nitride, a conductive metal carbide, a conductive metal oxide, a conductive metal carbonitride, and a 2D material. However, embodiments of the present disclosure are not necessarily limited thereto.

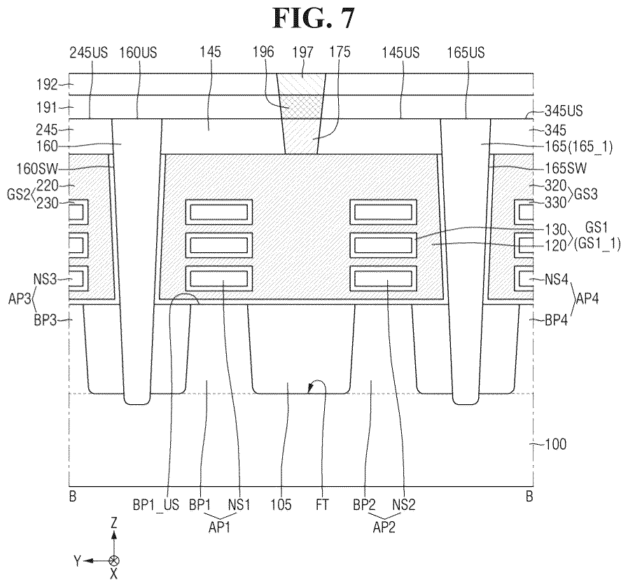

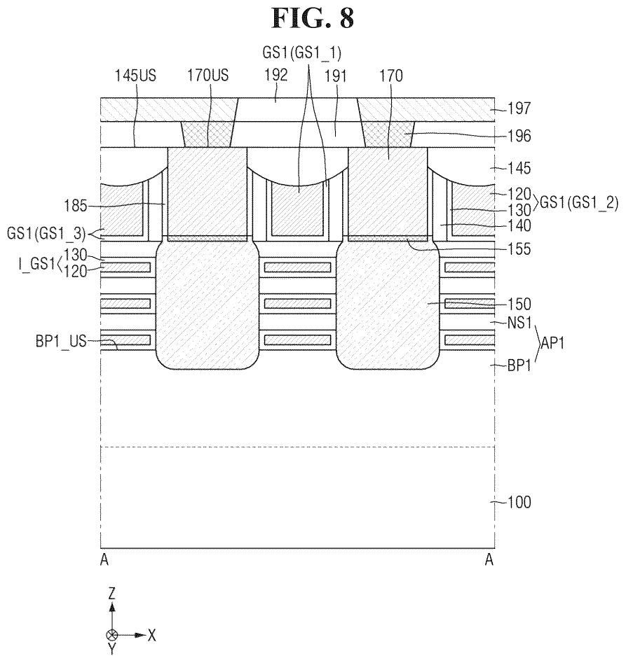

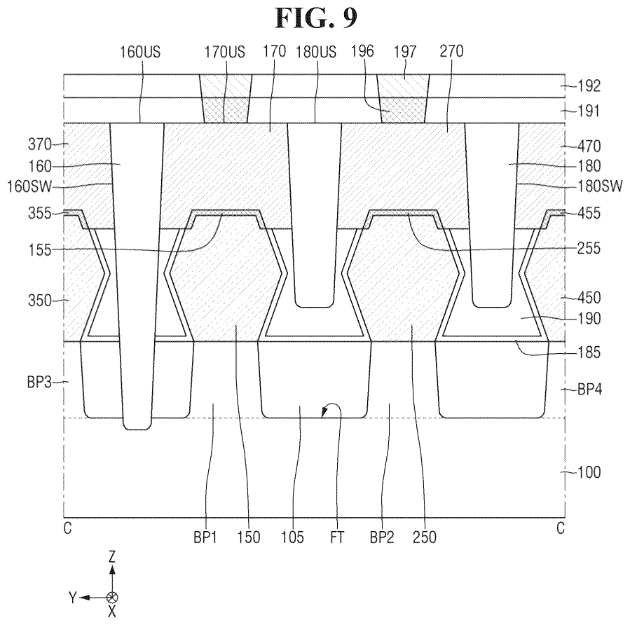

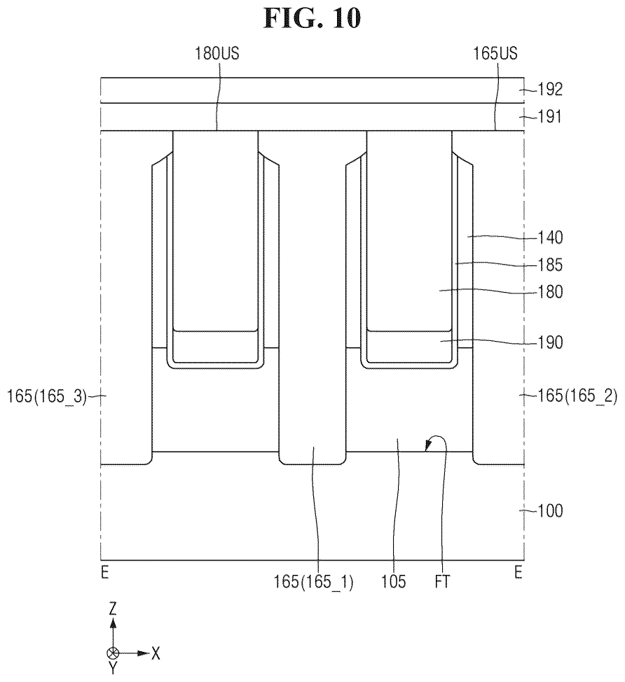

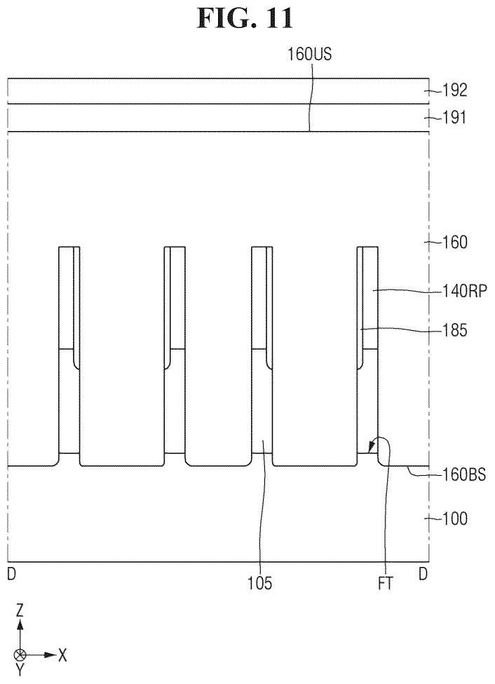

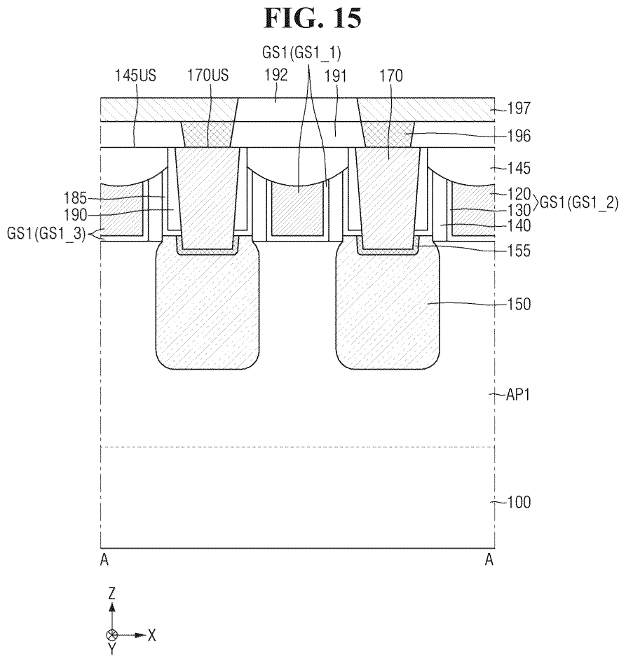

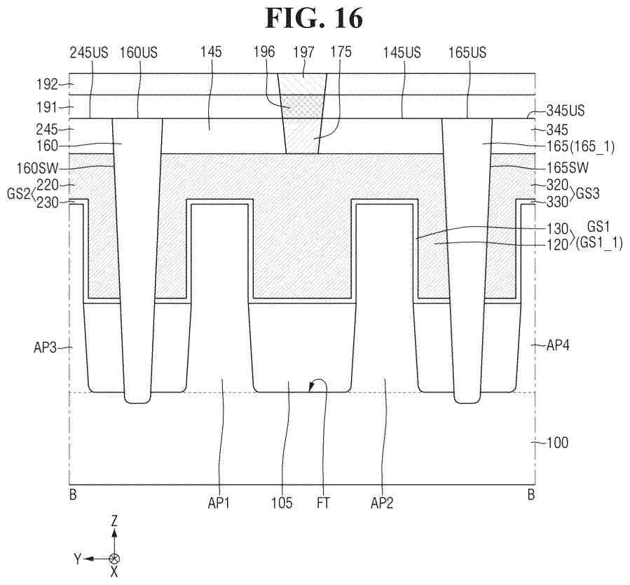

FIG. 7 is a cross-sectional view of a semiconductor device according to an embodiment of the present disclosure. FIGS. 8 through 10 are cross-sectional views of a semiconductor device according to some embodiments of the present disclosure. FIGS. 11 through 14 are cross-sectional views of semiconductor devices according to some embodiments of the present disclosure. FIGS. 15 and 16 are cross-sectional views of semiconductor devices according to some embodiments of the present disclosure. For convenience, the semiconductor devices of FIGS. 7 through 16 will hereinafter be described, focusing mainly on the differences with the semiconductor device of FIGS. 1 through 6.

Referring to FIG. 7, in an embodiment the first gate insulating films 130 and second gate insulating films 230 may extend in the third direction Z directly along sidewalls 160SW of a line gate isolation structure 160.

The first gate insulating films 130 and third gate insulating films 330 may extend in the third direction Z directly along sidewalls 165SW of point gate isolation structures 165.

First gate electrodes 120 and second gate electrodes 220 may not directly contact the sidewalls 160SW of the line gate isolation structure 160. Similarly, the first gate electrodes 120 and third gate electrodes 320 may not directly contact the sidewalls 165SW of the point gate isolation structures 165.

Referring to FIGS. 8 through 10, in an embodiment the semiconductor device may further include contact separation structures 180, which are disposed between (e.g., disposed directly therebetween) second source/drain contacts 270 and fourth source/drain contacts 470 (e.g., in the second direction Y).

In an embodiment, the contact separation structures 180 may be disposed between (e.g., disposed directly therebetween) first source/drain contacts 170 and the second source/drain contacts 270. The contact separation structures 180 may separate source/drain contacts that are adjacent to each other in the second direction Y.

In an embodiment, the second source/drain contacts 270 and the fourth source/drain contacts 470 may directly contact sidewalls 180SW of contact separation structures 180 that are disposed between the second source/drain contacts 270 and the fourth source/drain contacts 470. The first source/drain contacts 170 and the second source/drain contact 270 may directly contact sidewalls 180SW of contact separation structures 180 that are disposed between the first source/drain contacts 170 and the second source/drain contacts 270.

The contact separation structures 180 may not be disposed between the first source/drain contacts 170 and third source/drain contacts 370 (e.g., in the second direction Y). For example, the first source/drain contacts 170 and the third source/drain contacts 370 may be separated by a line gate isolation structure 160 (e.g., in the second direction Y). The first source/drain contacts 170 and the third source/drain contacts 370 may directly contact sidewalls 160SW of the line gate isolation structure 160.

The contact separation structures 180 may be disposed within a first interlayer insulating film 190 and may not extend to the field insulating film 105.

The contact separation structures 180 may not separate a source/drain etch stop film 185. A portion of the first interlayer insulating film 190 may be disposed between the field insulating film 105 and the contact separation structures 180. In an embodiment, the width of the contact separation structures 180 in the second direction Y may increase as a distance from the field insulating film 105 increases.

In an embodiment, upper surfaces 180US of the contact separation structures 180 may be on the same plane (e.g., in the third direction Z) as an upper surface 160US of the line gate isolation structure 160. The upper surfaces 180US of the contact separation structures 180 may also be on the same plane (e.g., in the third direction Z) as upper surfaces 165US of the point gate isolation structures 165.

The contact separation structures 180 include an insulating material. For example, in an embodiment, the contact separation structures 180 may include at least one of SiN, SiON, SiO₂, SiOCN, SiBN, SiOBN, SiOC, AlO, and a combination thereof. However, embodiments of the present disclosure are not necessarily limited thereto. The contact separation structures 180 are illustrated as being single layers. However, embodiments of the present disclosure are not necessarily limited thereto.

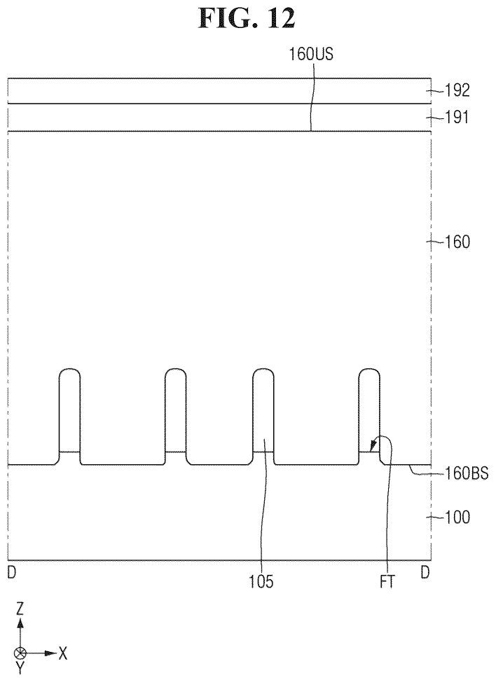

Referring to FIGS. 11 and 12, in some embodiments, a lower surface 160BS of a line gate isolation structure 160 may have a rugged or corrugated shape.

For example, in a embodiment, the line gate isolation structure 160 may include an extension extending in the first direction X and protrusions extending from the extension towards the substrate 100 (e.g., in the third direction Z). Portions of a field insulating film 105 may be disposed between the protrusions of the line gate isolation structure 160 that are adjacent to each other in the first direction X.

Referring to FIG. 11, in an embodiment, spacer residue patterns 140RP and portions of a source/drain etch stop film 185 may be disposed between the line gate isolation structure 160 and the field insulating film 105. The spacer residue patterns 140RP may be portions of spacers that are not removed but remain after an etching process for forming the line gate isolation structure 160.

Referring to FIG. 12, portions of the extension of the line gate isolation structure 160 may be recessed into the field insulating film 105. The spacer residue patterns 140RP and the source/drain etch stop film 185 do not remain between the protrusions of the line gate isolation structure 160 that are adjacent in the first direction X.

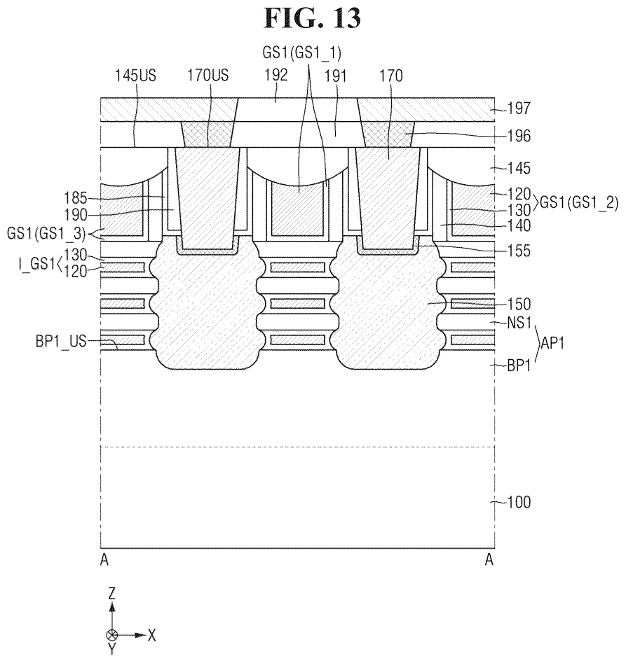

Referring to FIG. 13, in an embodiment, each of a plurality of first source/drain patterns 150 may include a plurality of width expansion areas.

The width expansion areas may include portions in which the width of the width expansion areas (e.g., in the first direction X) increases away from a substrate 100 and portions where the width of the width expansion areas decreases (e.g., in the first direction X) away from the substrate 100. The exterior of the first source/drain patterns 150, which are in direct contact with first sheet patterns NS1 and first inner gate structures I_GS1, may have a wavy shape.

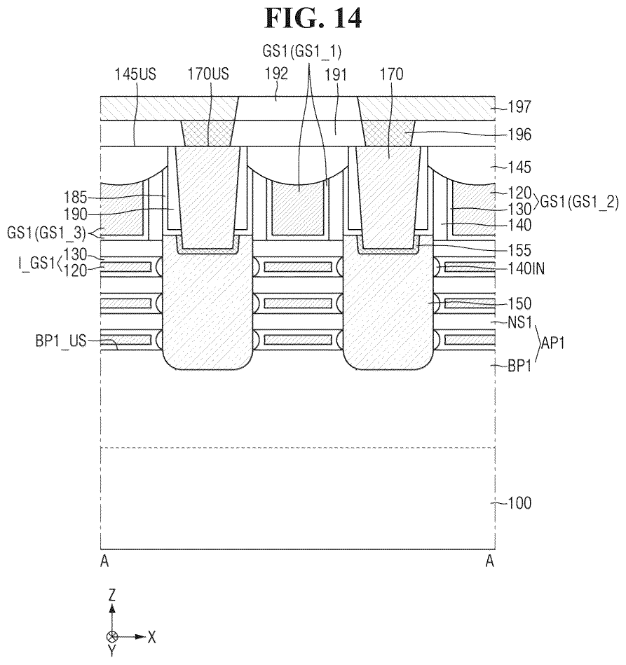

Referring to FIG. 14, in an embodiment the semiconductor device may further include a plurality of inner spacers 140IN.

In an embodiment, the inner spacers 140IN may be disposed between first sheet patterns NS1 that are adjacent in the third direction Z and between a first base pattern BP1 and the first sheet patterns NS1. The inner spacers 140IN may be disposed between first inner gate structures I_GS1 and first source/drain patterns 150 (e.g., in the first direction X). In an embodiment, the first inner gate structures I_GS1 may not directly contact the first source/drain patterns 150.

Referring to FIGS. 15 and 16, in some embodiments, first, second, third, and fourth active patterns AP1, AP2, AP3, and AP4 may not include sheet patterns (“NS1”, “NS2”, “NS3”, and “NS4” of FIG. 3).

In an embodiment, first inner gate structures (“I_GS1” of FIG. 2) are not disposed between the first source/drain patterns 150.

In an embodiment, in a first transistor formation region R1_MOS, two active patterns may be disposed on either side of a line gate isolation structure 160. However, embodiments of the present disclosure are not necessarily limited thereto. Similarly, in a second transistor formation region R2_MOS, two active patterns may be disposed on either side of each point gate isolation structure 165. However, embodiments of the present disclosure are not necessarily limited thereto.

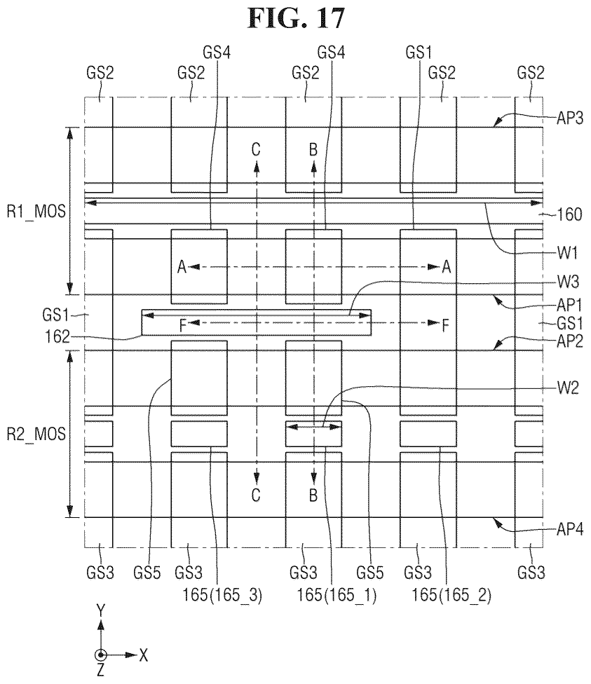

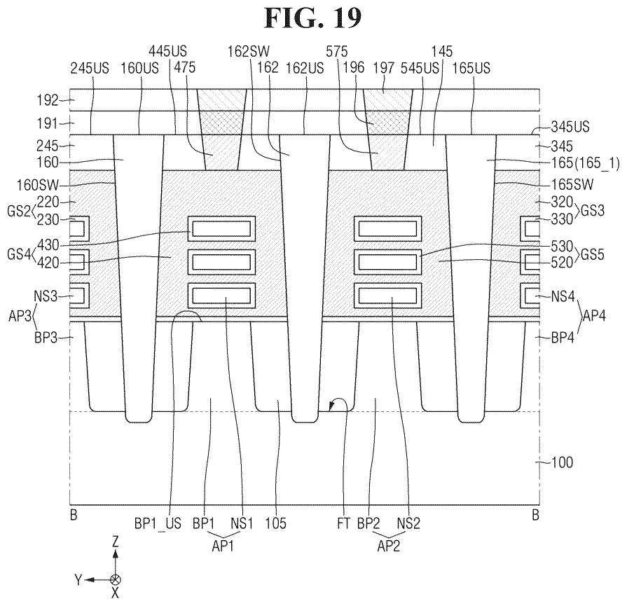

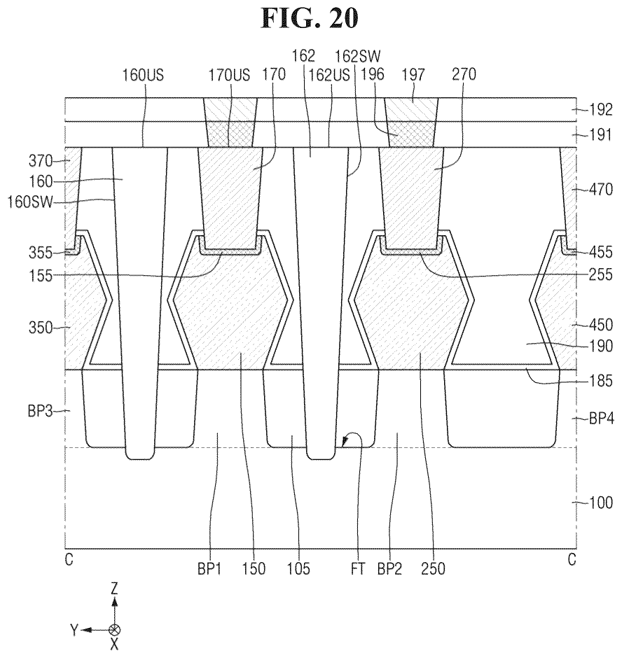

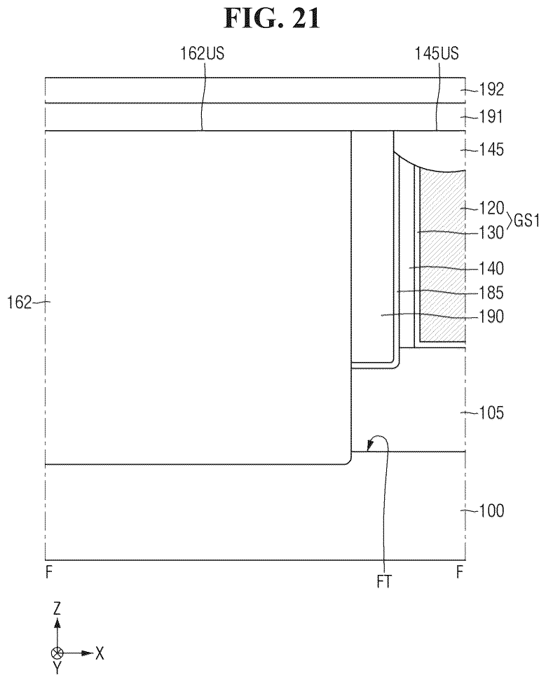

FIGS. 17 through 21 illustrate a semiconductor device according to some embodiments of the present disclosure. For convenience, the semiconductor device of FIGS. 17 through 21 will hereinafter be described, focusing mainly on the differences with the semiconductor device of FIGS. 1 through 6.

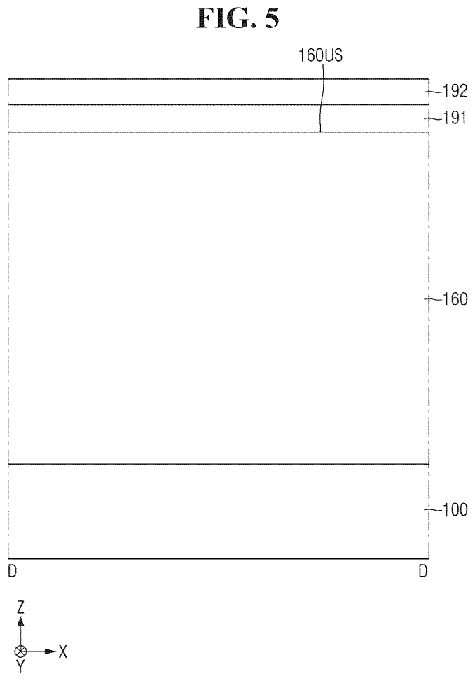

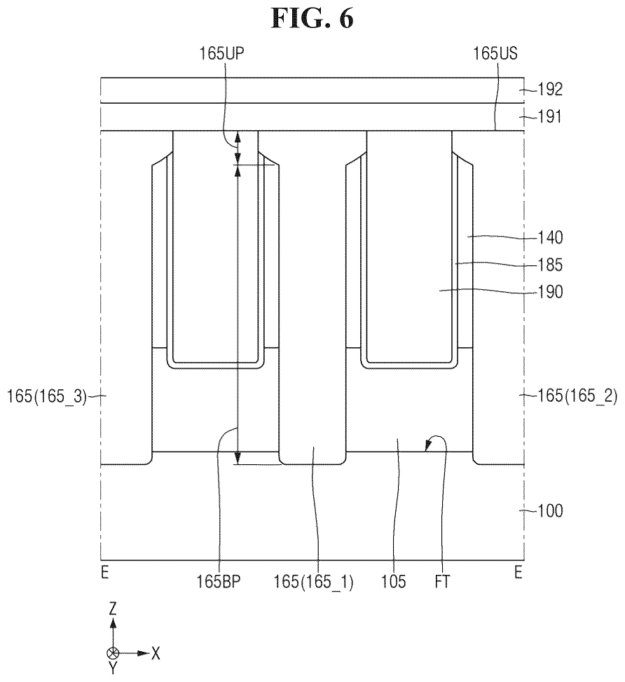

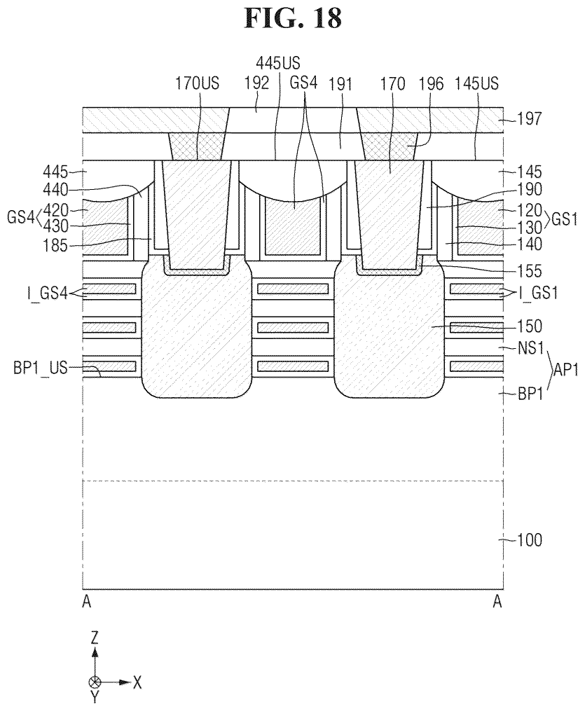

FIG. 17 is a layout view of a semiconductor device according to an embodiment of the present disclosure. FIGS. 18 through 21 are cross-sectional views taken along lines A-A, B-B, C-C, and F-F, respectively, of FIG. 17. Cross-sectional views, taken along the first direction X, of a line gate isolation structure 160 and point gate isolation structures 165 may be the same as illustrated in FIGS. 5 and 6.

Referring to FIGS. 17 through 21, the semiconductor device may further include an insert gate isolation structure 162, which is disposed between a first active pattern AP1 and a second active pattern AP2 (e.g., in the second direction Y).

The insert gate isolation structure 162 may be disposed between a first transistor formation region R1_MOS and a second transistor formation region R2_MOS (e.g., in the second direction Y). For example, in an embodiment the first transistor formation region R1_MOS may be a PMOS formation region, and the second transistor formation region R2_MOS may be an NMOS formation region.

The insert gate isolation structure 162 may be disposed between a line gate isolation structure 160 and point gate isolation structures 165 (e.g., in the second direction Y). The insert gate isolation structure 162 may be spaced apart from both the line gate isolation structure 160 and the point gate isolation structures 165 in the second direction Y.

In an embodiment, fourth gate structures GS4 and fifth gate structures GS5 may be disposed between the line gate isolation structure 160 and the point gate isolation structures 165 (e.g., in the second direction Y). The fourth gate structures GS4 may be disposed between the insert gate isolation structure 162 and the line gate isolation structure 160 (e.g., in the second direction Y). The fifth gate structures GS5 may be disposed between the insert gate isolation structure 162 and the point gate isolation structures 165 (e.g., in the second direction Y).

In an embodiment, first gate structures GS1 that are each divided into two parts by the insert gate isolation structure 162 may become the fourth gate structures GS4 and the fifth gate structures GS5. In an embodiment, the fourth gate structures GS4 and the fifth gate structures GS5 may be aligned with one another in the second direction Y.

The insert gate isolation structure 162 will be described later in further detail.

In an embodiment, the fourth gate structures GS4 may be disposed on (e.g., disposed directly thereon) the first active pattern AP1. fourth gate structures GS4 may intersect the first active pattern AP1. The fourth gate structures GS4 may also intersect a first base pattern BP1. The fourth gate structures GS4 may surround each of a plurality of first sheet patterns NS1.

In an embodiment, the fifth gate structures GS5 may be disposed on (e.g., disposed directly thereon) the second active pattern AP2. The fifth gate structures GS5 may intersect the second active pattern AP2. The fifth gate structures GS5 may also intersect a second base pattern BP2. The fifth gate structures GS5 may surround each of a plurality of second sheet patterns NS2.

In an embodiment, the fourth gate structures GS4 may include fourth gate electrodes 420 and fourth gate insulating films 430. The fifth gate structures GS5 may include fifth gate electrodes 520 and fifth gate insulating films 530.

The fourth gate structures GS4 may include a plurality of fourth inner gate structures I_GS4, which are disposed between the first base pattern BP1 and first sheet patterns NS1 that are adjacent in the third direction Z and between the first sheet patterns NS1. In an embodiment, the fifth gate structures GS5 may include fifth inner gate structures, which are disposed between the second base pattern BP2 and second sheet patterns NS2 that are adjacent in the third direction Z and between the second sheet patterns NS2.

The descriptions of the fourth gate structures GS4 and the fifth gate structures GS5 are substantially the same as the descriptions of the first gate structures GS1, second gate structures GS2, and third gate structures GS3, and thus a repeated description will be omitted for economy of description.

Fourth gate spacers 440 may be disposed on the sidewalls of the fourth gate structures GS4. In an embodiment, fifth gate spacers may be disposed on the sidewalls of the fifth gate structures GS5.

In an embodiment, fourth gate capping patterns 445 may be disposed on (e.g., disposed directly thereon in the third direction Z) the fourth gate electrodes 420. Fifth gate capping patterns 545 may be disposed on (e.g., disposed directly thereon in the third direction Z) the fifth gate electrodes 520. In an embodiment, upper surfaces 445US of the fourth gate capping patterns 445 may be on the same plane (e.g., in the third direction Z) as a upper surface 160US of the line gate isolation structure 160. Similarly, upper surfaces 545US of the fifth gate capping patterns 545 may be on the same plane (e.g., in the third direction Z) as upper surfaces 165US of the point gate isolation structures 165.

The insert gate isolation structure 162 may be disposed on (e.g., disposed directly thereon) the substrate 100. The insert gate isolation structure 162 may be disposed within a first interlayer insulating film 190 and a field insulating film 105. In an embodiment, the insert gate isolation structure 162 may directly contact both the first interlayer insulating film 190 and the field insulating film 105. A portion of the insert gate isolation structure 162 may be disposed within the substrate 100.

Alternatively, in an embodiment the insert gate isolation structure 162 may be spaced apart from the substrate 100. For example, a portion of the field insulating film 105 may be disposed between the insert gate isolation structure 162 and the substrate 100.

The insert gate isolation structure 162 may separate the fourth gate structures GS4 and the fifth gate structures GS5 that are adjacent to the fourth gate structures GS4 in the second direction Y. The fourth gate structures GS4 and the fifth gate structures GS5 may directly contact the insert gate isolation structure 162. The fourth gate structures GS4 may directly contact the line gate isolation structure 160. The fifth gate structures GS5 may directly contact the point gate isolation structures 165. The fourth gate structures GS4 and the fifth gate structures GS5 may directly contact sidewalls 162SW of the insert gate isolation structure 162.

The insert gate isolation structure 162 may separate the fourth gate capping patterns 445 and the fifth gate capping patterns 545 from each other. For example, an upper surface 162US of the insert gate isolation structure 162 may be on the same plane (e.g., in the third direction Z) as the upper surfaces 445US of the fourth gate capping patterns 445 and the upper surfaces 545US of the fifth gate capping patterns 545.

In an embodiment, the insert gate isolation structure 162 may have a linear shape extending longitudinally in the first direction X. The insert gate isolation structure 162 may cut fewer gate structures than the line gate isolation structure 160.

A length W3 of the insert gate isolation structure 162 in the first direction X may be less than a length W1 of the line gate isolation structure 160. The length W3 of the insert gate isolation structure 162 in the first direction X may be greater than a length W2 of the point gate isolation structures 165.

The number of first gate structures GS1 and fourth gate structures GS4 in direct contact with the line gate isolation structure 160 may be greater than the number of fourth gate structures GS4 in direct contact with the insert gate isolation structure 162. The number of fourth gate structures GS4 in direct contact with the insert gate isolation structure 162 may be greater than the number of fourth gate structures GS4 in direct contact with each of the point gate isolation structures 165. One insert gate isolation structure 162 may separate multiple fourth gate structures GS4. For example, in an embodiment shown in FIG. 17, one insert gate isolation structure 162 separates two fourth gate structures GS4 from two fifth gate structures GS5 (e.g., in the second direction Y). However, embodiments of the present disclosure are not necessarily limited thereto.

Since the insert gate isolation structure 162 separates multiple fourth gate structures GS4, first source/drain patterns 150 and second source/drain patterns 250 may overlap with the insert gate isolation structure 162 in the second direction Y. The insert gate isolation structure 162 may be disposed between first source/drain contacts 170 and second source/drain contacts 270.

For example, in an embodiment the insert gate isolation structure 162 may separate three or more fourth gate structures GS4. In an embodiment, the insert gate isolation structure 162 may separate only one fourth gate structure GS4. In this embodiment, the insert gate isolation structure 162 may protrude into the first interlayer insulating film 190. As a result, the first source/drain patterns 150 and the second source/drain patterns 250 may overlap with the insert gate isolation structure 162 in the second direction Y.

In an embodiment, the insert gate isolation structure 162 may include at least one of SiN, SiON, SiO₂, SIOCN, SiBN, SiOBN, SiOC, aluminum oxide AlO, and a combination thereof. However, embodiments of the present disclosure are not necessarily limited thereto.

For example, the insert gate isolation structure 162 may include a material having tensile stress characteristics. In an embodiment, the insert gate isolation structure 162 may include the same material as the line gate isolation structure 160 and the point gate isolation structures 165. For example, in an embodiment, the insert gate isolation structure 162, the line gate isolation structure 160, and the point gate isolation structures 165 may include silicon nitride. However, embodiments of the present disclosure are not necessarily limited thereto.

Fourth gate contacts 475 are disposed on (e.g., disposed directly thereon in the third direction Z) the fourth gate electrodes 420. The fourth gate contacts 475 are connected to (e.g., directly connected thereto) the fourth gate electrodes 420. Fifth gate contacts 575 are disposed on (e.g., disposed directly thereon in the third direction Z) the fifth gate electrodes 520. The fifth gate contacts 575 are connected to (e.g., directly connected thereto) the fifth gate electrodes 520.

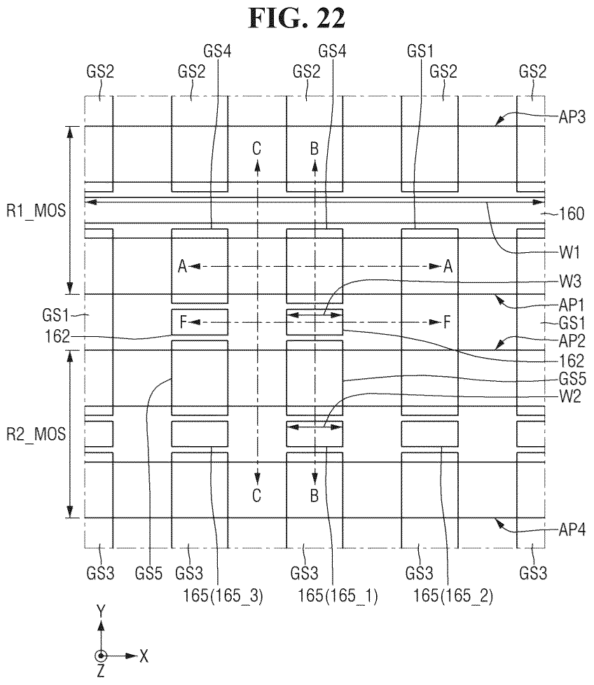

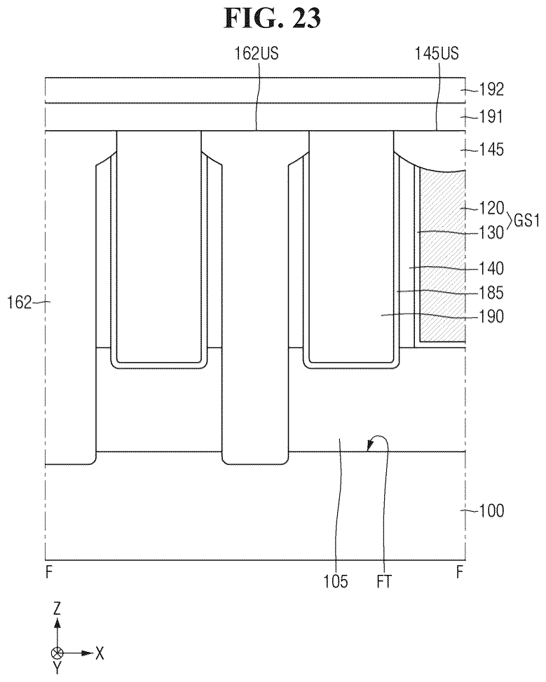

FIGS. 22 and 23 are drawings for explaining a semiconductor device according to some embodiments of the present disclosure. For convenience, the semiconductor device of FIGS. 22 and 23 will hereinafter be described, focusing mainly on the semiconductor device of FIGS. 17 through 21 and a repeated description may be omitted for economy of description.

FIG. 22 is a layout view of a semiconductor device according to an embodiment of the present disclosure. FIG. 23 is a cross-sectional view taken along line F-F of FIG. 22. Cross-sectional views taken along lines A-A, B-B, and C-C of FIG. 22 may be the same as illustrated in FIGS. 18 through 20.

Referring to FIGS. 22 and 23, insert gate isolation structures 162 may have a similar contact shape as the point gate isolation structures 165.

For example, in an embodiment a first transistor formation region R1_MOS may be an NMOS formation region, and the second transistor formation region R2_MOS may be a PMOS formation region.

Each of the insert gate isolation structures 162, like each of the point gate isolation structures 165, may cut only one gate structure. A description of the shape of the insert gate isolation structures 162 may be substantially the same as the description of the shape of the point gate isolation structures 165.

A length W3 of the insert gate isolation structures 162 in the first direction X may be less than a length W1 of a line gate isolation structure 160 in the first direction X. The length W3 of the insert gate isolation structures 162 in the first direction X may be the same as a length W2 of the point gate isolation structures 165 in the first direction X.

The number of fourth gate structures GS4 in direct contact with each of the insert gate isolation structures 162 is the same as the number of fourth gate structures GS4 in direct contact with each of the point gate isolation structures 165. One insert gate isolation structure 162 may divide one fourth gate structure GS4.

Since each of the insert gate isolation structures 162 divides only one fourth gate structure GS4, first source/drain patterns 150 and second source/drain patterns 250 do not overlap with the insert gate isolation structures 162 in the second direction Y. The insert gate isolation structures 162 may not be disposed between first source/drain contacts 170 and second source/drain contacts 270.

The insert gate isolation structures 162 may include, for example, a material with compressive stress characteristics. In an embodiment, the insert gate isolation structures 162 may include the same material as the line gate isolation structure 160 and the point gate isolation structures 165. For example, in an embodiment, the insert gate isolation structures 162, the line gate isolation structure 160, and the point gate isolation structures 165 may include silicon nitride. However, embodiments of the present disclosure are not necessarily limited thereto.

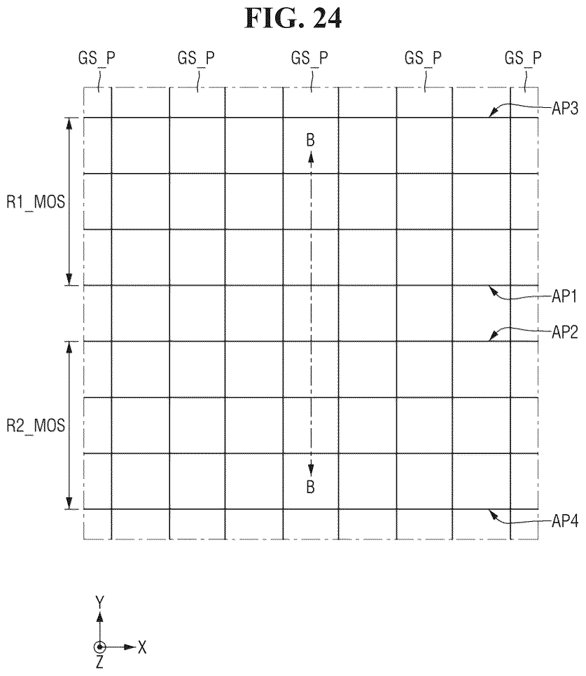

FIGS. 24 through 31 are drawings illustrating intermediate steps of a method of manufacturing a semiconductor device according to some embodiments of the present disclosure.

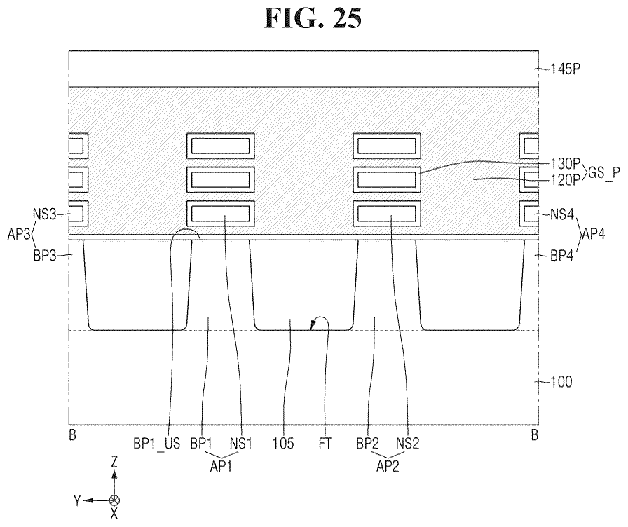

Referring to FIGS. 24 and 25, first pre-gate structures GS_P may be formed on a substrate 100.

In an embodiment, the first pre-gate structures GS_P may intersect first, second, third, and fourth active patterns AP1, AP2, AP3, and AP4. The first pre-gate structures GS_P may be disposed on first, second, third, and fourth base patterns BP1, BP2, BP3, and BP4. The first pre-gate structures GS_P may surround first sheet patterns NS1, second sheet patterns NS2, third sheet patterns NS3, and fourth sheet patterns NS4. First pre-gate capping patterns 145P may be formed on (e.g., formed directly thereon in the third direction Z) the first pre-gate structures GS_P.

In an embodiment, the first pre-gate structures GS_P may include first pre-gate electrodes 120P and first pre-gate insulating films 130P. The first pre-gate electrodes 120P may include a conductive material containing a metal. The first pre-gate insulating films 130P may include insulating films with a high-k dielectric material.

The first pre-gate structures GS_P are illustrated as including metal gate electrodes formed by a replacement metal gate process. However, embodiments of the present disclosure are not necessarily limited thereto. Alternatively, in an embodiment, the first pre-gate structures GS_P may include dummy mold electrodes, which are for securing positions for forming metal gate electrodes to be formed, and dummy gate insulating films. In this embodiment, the dummy mold electrodes may include, but are not necessarily limited to, a semiconductor material and the dummy gate insulating films may include, but are not necessarily limited to, silicon oxide.

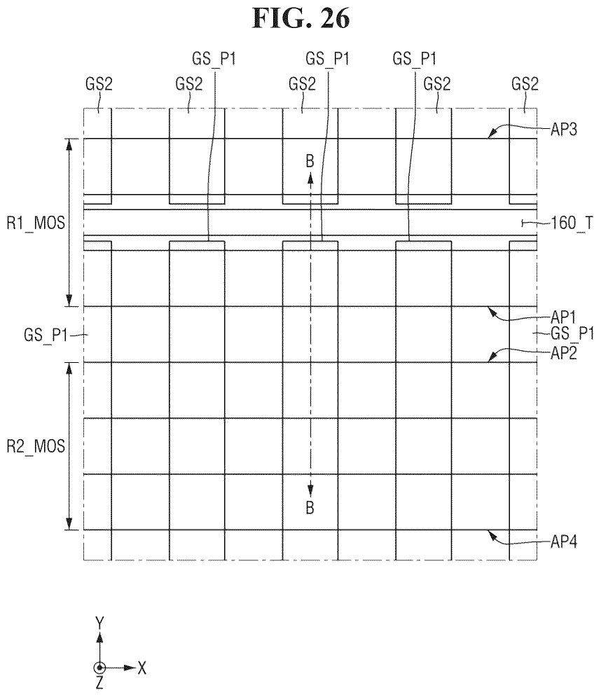

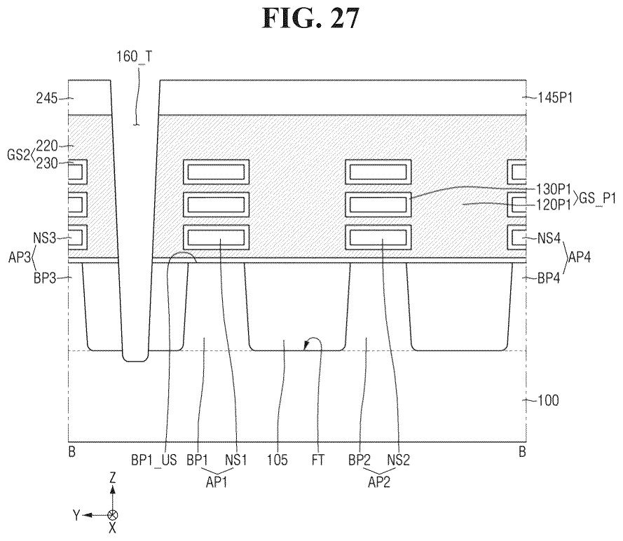

Referring to FIGS. 26 and 27, a line trench 160_T may be formed between a first active pattern AP1 and a third active pattern AP3 (e.g., in the second direction Y).

The line trench 160_T extends longitudinally in the first direction X. The line trench 160_T may have a linear shape.

The line trench 160_T may divide the first pre-gate structures GS_P. As a result, second pre-gate structures GS_P1 and second gate structures GP2.

The line trench 160_T may divide first pre-gate capping patterns 145P (e.g., in the second direction Y). As a result, second gate capping patterns 245 and first pre-gate capping patterns 145P1 may be formed.

In an embodiment, the second pre-gate structures GS_P1 may intersect the first, second, and fourth active patterns AP1, AP2, and AP4. In an embodiment, the second pre-gate structures GS_P1 may include second pre-gate electrodes 120P1 and second pre-gate insulating films 130P1.

Referring to FIG. 28, a line gate isolation structure 160 may be formed within the line trench 160_T.

The line gate isolation structure 160 may fill the line trench 160_T. For example, in an embodiment the line gate isolation structure 160 may be formed using one of atomic layer deposition (ALD), chemical vapor deposition (CVD), and physical vapor deposition (PVD).

The stress characteristics of a material layer may vary depending on how the material of the material layer is deposited. For example, the stress characteristics of a silicon nitride layer formed by ALD may differ from the stress characteristics of a silicon nitride layer formed by CVD. For example, if a silicon nitride formed by ALD exhibits tensile stress characteristics, a silicon nitride layer formed by CVD may exhibit compressive stress characteristics, or vice versa.

In an embodiment, the method to form the line gate isolation structure 160 may be determined based on whether the line gate isolation structure 160 is to be disposed in either a PMOS formation region or an NMOS formation region.

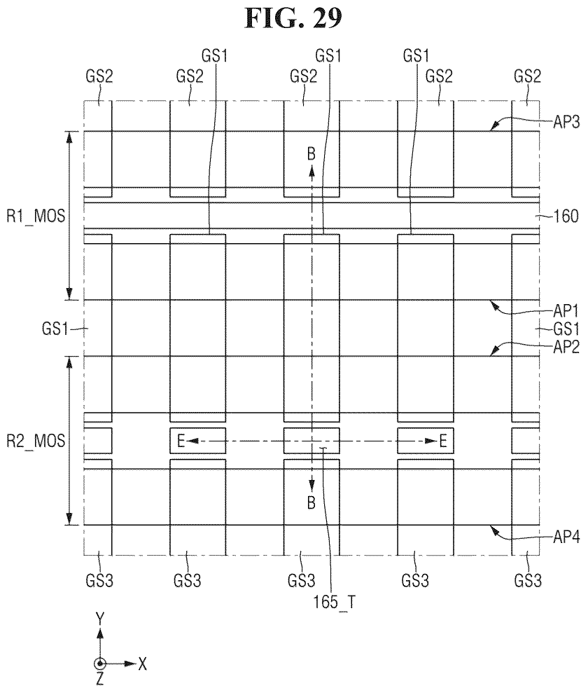

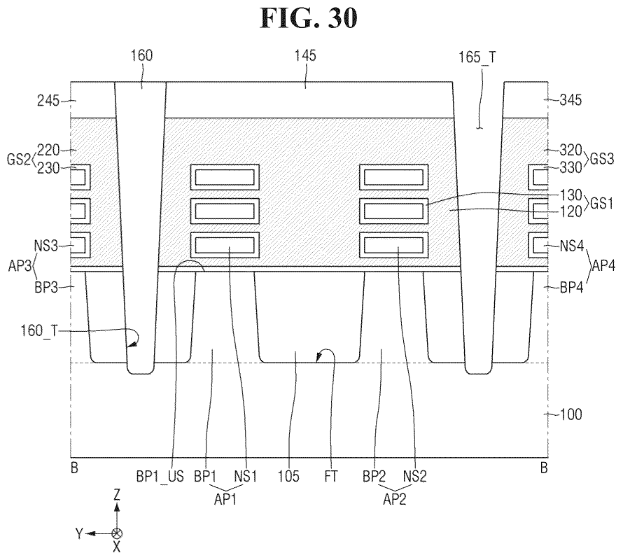

Referring to FIGS. 29 and 30, point trenches 165_T may be formed between the second and fourth active patterns AP2 and AP4 (e.g., in the second direction Y).

The point trenches 165_T may be formed where the second pre-gate structures GS_P1 are disposed. The point trenches 165_T may have a contact hole shape.

The point trenches 165_T may divide the second pre-gate structures GS_P1 (e.g., in the second direction Y). As a result, first gate structures GP1 and third gate structures GP3 may be formed.

The point trenches 165_T may divide the second pre-gate capping patterns 145P1 (e.g., in the second direction Y). As a result, first gate capping patterns 145 and third gate capping patterns 345 may be formed.

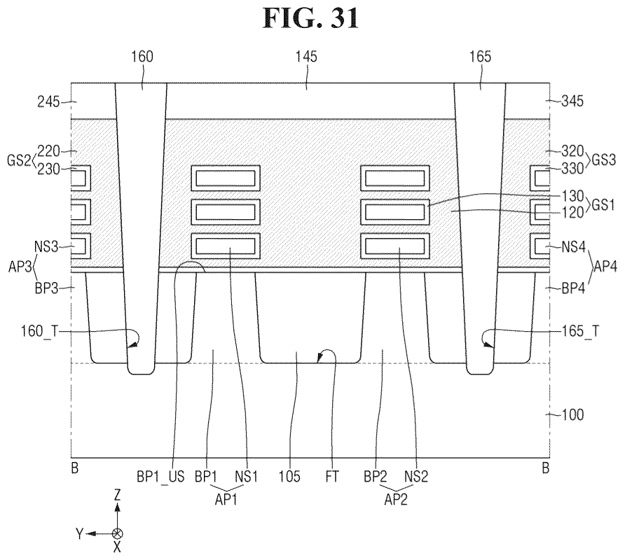

Referring to FIG. 31, point gate isolation structures 165 may be formed within the point trenches 165_T.

The point gate isolation structures 165 may fill the point trenches 165_T. In an embodiment, the point gate isolation structures 165 may be formed by, for example, using ALD, CVD, and PVD.

The line gate isolation structure 160 may be formed before the formation of the point gate isolation structures 165. However, embodiments of the present disclosure are not necessarily limited thereto. Alternatively, the point gate isolation structures 165 may be formed before the formation of the line gate isolation structure 160.

For example, in an embodiment in which a first transistor formation region R1_MOS is a PMOS formation region and a second transistor formation region R2_MOS is an NMOS formation region, an insert gate isolation structure (“162” of FIG. 17) may be formed together with the line gate isolation structure 160.

In an embodiment in which the first transistor formation region R1_MOS is an NMOS formation region and the second transistor formation region R2_MOS is a PMOS formation region, the insert gate isolation structure 162 may be formed together with the point gate isolation structures 165.

In concluding the detailed description, those skilled in the art will appreciate that many variations and modifications may be made to the described embodiments without substantially departing from the principles of the present disclosure. Therefore, the described embodiments of the present disclosure are used in a generic and descriptive sense only and not for purposes of limitation.

What is claimed is:

1. A semiconductor device comprising:
a first gate isolation structure;
a second gate isolation structure spaced apart from the first gate isolation structure in a first direction;
a first active pattern disposed between the first and second gate isolation structures, the first active pattern extending longitudinally in a second direction crossing the first direction;
a second active pattern disposed between the first and second gate isolation structures, the second active pattern extending longitudinally in the second direction and spaced apart from the first active pattern in the first direction; and
gate structures disposed between the first and second gate isolation structures, the gate structures directly contact the first and second gate isolation structures,
wherein a length of the first gate isolation structure in the second direction is greater than a length of the second gate isolation structure in the second direction.

2. The semiconductor device of claim 1, wherein:
the first active pattern is disposed in a P-type metal-oxide semiconductor (PMOS) formation region,
the second active pattern is disposed in an N-type metal-oxide semiconductor (NMOS) formation region, and
the first active pattern is closer to the first gate isolation structure than the second active pattern.

3. The semiconductor device of claim 2, further comprising:
an insert gate isolation structure disposed between the first and second active patterns in the first direction,
wherein:
the gate structure includes first and second gate structures that are divided by the insert gate isolation structure; and
a length of the insert gate isolation structure in the second direction is greater than a length of the second gate isolation structure in the second direction.

4. The semiconductor device of claim 1, wherein:
the first active pattern is disposed in an NMOS formation region;
the second active pattern is disposed in a PMOS formation region; and
the first active pattern is closer to the first gate isolation structure than the second active pattern.

5. The semiconductor device of claim 4, further comprising:
an insert gate isolation structure disposed between the first and second active patterns in the first direction,
wherein:
the gate structure includes first and second gate structures that are divided by the insert gate isolation structure, and
a length of the insert gate isolation structure in the second direction is greater than a length of the second gate isolation structure in the second direction.

6. The semiconductor device of claim 1, wherein:
the first gate isolation structure has a linear shape extending longitudinally in the second direction; and
the second gate isolation structure has a contact shape.

7. The semiconductor device of claim 6, wherein:
the gate structures include first and second gate structures that are spaced apart from each other in the second direction,
the second gate isolation structure includes first and second sub-gate isolation structures that are spaced apart from each other in the second direction,
the first gate isolation structure directly contacts the first and second gate structures,
the first sub-gate isolation structure directly contacts the first gate structure, but does not directly contact the second gate structure, and
the second sub-gate isolation structure directly contacts the second gate structure, but does not directly contact the first gate structure.

8. The semiconductor device of claim 1, wherein the first and second gate isolation structures include a same material as each other.

9. The semiconductor device of claim 1, wherein:
the gate structures include gate electrodes and gate insulating films; and
the gate electrodes directly contact sidewalls of the first gate isolation structure.

10. The semiconductor device of claim 1, wherein:
the gate structures include gate electrodes and gate insulating films; and
the gate insulating films extend in a third direction directly along sidewalls of the first gate isolation structure.

11. The semiconductor device of claim 1, wherein:
the first active pattern includes a lower pattern and sheet patterns that are spaced apart from the lower pattern; and
the gate structures surround the sheet patterns.

12. A semiconductor device comprising:
a first gate isolation structure;
a second gate isolation structure spaced apart from the first gate isolation structure in a first direction;
a first active pattern disposed between the first and second gate isolation structures, the first active pattern extending longitudinally in a second direction crossing the first direction;
a second active pattern disposed between the first and second gate isolation structures, the second active pattern extending longitudinally in the second direction and spaced apart from the first active pattern in the first direction; and
a plurality of gate structures intersecting the first and second gate isolation structures and extending longitudinally in the first direction,
wherein a number of gate structures directly contacting the first gate isolation structure is greater than a number of gate structures directly contacting the second gate isolation structure.

13. The semiconductor device of claim 12, wherein the second gate isolation structure directly contacts the first gate structure.

14. The semiconductor device of claim 12, wherein:
the first active pattern is disposed in a P-type metal-oxide semiconductor (PMOS) formation region;
the second active pattern is an N-type metal-oxide semiconductor (NMOS) formation region; and
the first active pattern is closer to the first gate isolation structure than the second active pattern.

15. The semiconductor device of claim 14, wherein the first and second gate isolation structures include a material having tensile stress characteristics.

16. The semiconductor device of claim 12, wherein:
the first active pattern is disposed in an NMOS formation region;
the second active pattern is disposed in a PMOS formation region; and
the first active pattern is closer to the first gate isolation structure than the second active pattern.

17. The semiconductor device of claim 16, wherein the first and second gate isolation structures include a material having compressive stress characteristics.

18. The semiconductor device of claim 12, wherein the first and second gate isolation structures include a same material as each other.

19. A semiconductor device comprising:
a first gate isolation structure;
a second gate isolation structure spaced apart from the first gate isolation structure in a first direction;
a first active pattern disposed between the first and second gate isolation structures, the first active pattern including a first lower pattern extending longitudinally in the second direction and first sheet patterns that are spaced apart from the first lower pattern in a third direction that is a thickness direction crossing the first and second directions;
a second active pattern disposed between the first and second gate isolation structures, the second active pattern including a second lower pattern extending in the second direction and spaced apart from the first lower pattern in the first direction, and second sheet patterns that are spaced apart from the second lower pattern in the third direction;
gate structures disposed between the first and second gate isolation structures, the gate structures directly contacting the first and second gate isolation structures;
first source/drain patterns disposed on the first lower pattern, the first source/drain patterns are connected to the first sheet patterns and are doped with impurities of a first conductivity type; and
second source/drain patterns disposed on the second lower pattern, the second source/drain patterns are connected to the second sheet patterns and are doped with impurities of a second conductivity type that is different from the first conductivity type,
wherein:
the first gate isolation structure overlaps with the first source/drain patterns and the second source/drain patterns in the first direction; and
the second gate isolation structure does not overlap with the first source/drain patterns and the second source/drain patterns in the first direction.

20. The semiconductor device of claim 19, wherein the first and second gate isolation structures include a same material as each other.
